(19) United States
(12) Patent Application Publication
(10) Pub. No.: US 2025/0257218 A1
(43) Pub. Date: Aug. 14, 2025

(54) COMPOSITIONS FOR NEAR-INFRARED LIGHT-BLOCKING FILTERS, AND IMAGE SENSORS INCLUDING NEAR-INFRARED LIGHT-BLOCKING FILTERS

(71) Applicant: Samsung Electronics Co., Ltd., Suwon-si (KR)

(72) Inventors: Byeongeun Kwak, Suwon-si (KR); Jaepil Kim, Seoul-si (KR); Dongjun Lee, Seoul-si (KR); Joowon Lee, Suwon-si (KR); Hyunkyu Lee, Seoul-si (KR); Seungwon Kim, Suwon-si (KR); Songse Yi, Suwon-si (KR); Yeseul Lee, Suwon-si (KR)

(73) Assignee: Seoul National University R&DB Foundation, Seoul (KR)

(21) Appl. No.: 19/003,297

(22) Filed: Dec. 27, 2024

(30) Foreign Application Priority Data
Feb. 8, 2024 (KR) 10-2024-0019829

(51) Int. Cl. C09B 23/01; H10F 39/00

(52) U.S. Cl. CPC C09B 23/0066; H10F 39/8053; H10F 39/8063

(57) ABSTRACT

Provided is an image sensor including a substrate including a first surface and a second surface opposite to the first surface, and a near-infrared light-blocking filter disposed on the second surface of the substrate. The substrate includes a plurality of pixels, the plurality of pixels each includes a photoelectric conversion region, the near-infrared light-blocking filter includes a mixture of a first cyanine dye, a second cyanine dye, and a third cyanine dye, the first cyanine dye is represented by General Formula 1, the second cyanine dye is represented by General Formula 2, and the third cyanine dye is represented by General Formula 3 or General Formula 4.

### CROSS-REFERENCE TO RELATED APPLICATION

This application claims priority under 35 U.S.C. § 119 to Korean Patent Application No. 10-2024-0019829, filed on Feb. 8, 2024, in the Korean Intellectual Property Office, the disclosure of which is incorporated by reference herein in its entirety.

### FIELD

The inventive concept relates to a composition for a near-infrared light-blocking filter and an image sensor including a near-infrared light-blocking filter, and more particularly, to an image a sensor including a near-infrared light-blocking filter that includes a cyanine dye.

### BACKGROUND

A complementary metal oxide semiconductor (CMOS) image sensor includes a photoelectric conversion region formed within a silicon substrate, and the silicon substrate has a relatively high sensitivity to infrared light. When near-infrared light or infrared light is transmitted through a silicon substrate, distortion of a red image occurs. Therefore, a method of absorbing infrared light or near-infrared light by disposing the near-infrared light-blocking filter under a module lens has been suggested. However, the size of the near-infrared light-blocking filter is relatively large, which restricts miniaturization of the image sensor. In addition, a deviation in blocking characteristics depending on an angle of incidence is relatively large and noise is generated due to light leakage, which cause limitations.

### SUMMARY

In some embodiments, the inventive concept provides an image sensor including a composition for a near-infrared light-blocking filter, which has improved blocking characteristics, and a near-infrared light-blocking filter formed using the composition.

According to an aspect of the inventive concept, there is provided a composition for a near-infrared light blocking filter employed in an image sensor, the composition including a mixture of a first cyanine dye, a second cyanine dye, and a third cyanine dye, wherein the first cyanine dye is represented by General Formula 1 below, the second cyanine dye is represented by General Formula 2 below, and the third cyanine dye is represented by General Formula 3 or General Formula 4 below.

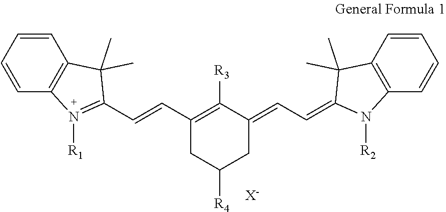

wherein, in General Formula 1, R₁ and R₂ are each independently a linear or branched alkyl group having a carbon number of 6 to 12, R₃ is at least one of a halogen element, a phenol group, a p-hydroxybenzoic acid group, a methylparaben group, a methyl p-aminobenzoate group, a p-aminobenzoic acid group, an aniline group, a benzenesulfinic acid group, and a diphenylamine group, R₄ is a n-butyl group, a sec-butyl group, an iso-butyl group, a tert-butyl group, a phenyl group, a benzyl group, a tert-butylphenyl group, a cyclopropyl group, a cyclobutyl group, a cyclopentyl group, a cyclohexyl group, a cyclohexenyl group, a cycloheptyl group, a cyclooctyl group, a methoxyl group, an ethoxyl group, or a propoxyl group, and X is a non-metallic element.

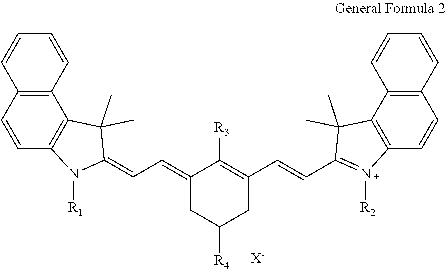

wherein, in General Formula 2, R₁ and R₂ are each independently a linear or branched alkyl group having a carbon number of 6 to 12, R₃ is at least one of a halogen element, a phenol group, a p-hydroxybenzoic acid group, a methylparaben group, a methyl p-aminobenzoate group, a p-aminobenzoic acid group, an aniline group, a benzenesulfinic acid group, and a diphenylamine group, R₄ is a n-butyl group, a sec-butyl group, an iso-butyl group, a tert-butyl group, a phenyl group, a benzyl group, a tert-butylphenyl group, a cyclopropyl group, a cyclobutyl group, a cyclopentyl group, a cyclohexyl group, a cyclohexenyl group, a cycloheptyl group, a cyclooctyl group, a methoxyl group, an ethoxyl group, or a propoxyl group, and X is a non-metallic element.

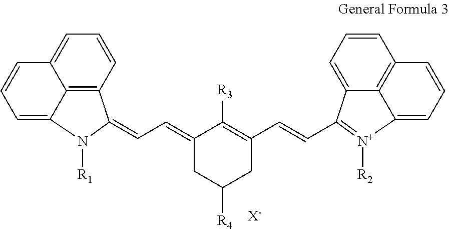

wherein, in General Formula 3, R₁ and R₂ are each independently a linear or branched alkyl group having a carbon number of 6 to 12, R₃ is at least one of a halogen element, a phenol group, a p-hydroxybenzoic acid group, a methylparaben group, a methyl p-aminobenzoate group, a p-aminobenzoic acid group, an aniline group, a benzenesulfinic acid group, and a diphenylamine group, R₄ is a n-butyl group, a sec-butyl group, an iso-butyl group, a tert-butyl group, a phenyl group, a benzyl group, a tert-butylphenyl group, a cyclopropyl group, a cyclobutyl group, a cyclopentyl group, a cyclohexyl group, a cyclohexenyl group, a cycloheptyl group, a cyclooctyl group, a methoxyl group, an ethoxyl group, or a propoxyl group, and X is a non-metallic element.

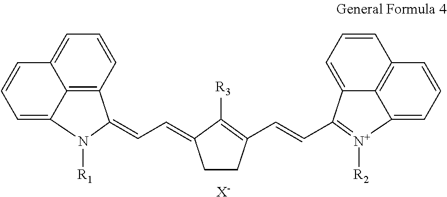

wherein, in General Formula 4, R₁ and R₂ are each independently a linear or branched alkyl group having a carbon number of 6 to 12, R₃ is at least one of a halogen element, a phenol group, a p-hydroxybenzoic acid group, a methylparaben group, a methyl p-aminobenzoate group, a p-aminobenzoic acid group, an aniline group, a benzenesulfinic acid group, and a diphenylamine group, and X is a non-metal element.

According to another aspect of the inventive concept, there is provided an image sensor including a substrate including a first surface and a second surface opposite to the first surface, and a near-infrared light-blocking filter disposed on the second surface of the substrate, wherein the substrate includes a plurality of pixels, the plurality of pixels each includes a photoelectric conversion region, the near-infrared light-blocking filter includes a mixture of a first cyanine dye, a second cyanine dye, and a third cyanine dye, the first cyanine dye is represented by General Formula 1, the second cyanine dye is represented by General Formula 2, and the third cyanine dye is represented by General Formula 3 or General Formula 4.

According to another aspect of the inventive concept, there is provided an image sensor including a substrate including a first surface and a second surface opposite to the first surface, an anti-reflection layer disposed on the second surface, a color filter disposed on the anti-reflection layer, a near-infrared light-blocking filter disposed on the color filter, and a microlens disposed on the near-infrared light-blocking filter, wherein the substrate includes a plurality of pixels, and the plurality of pixels each includes a photoelectric conversion region, the near-infrared light-blocking filter includes a mixture of a first cyanine dye, a second cyanine dye, and a third cyanine dye in a weight ratio of a:b:c, a is about 0.4 to about 0.6, b is about 0.5 to about 0.7, and c is about 0.9 to about 1.1, wherein the first cyanine dye includes a heptamethine cyanine dye, is configured to absorb light having a wavelength in a range of about 750 nm to about 850 nm, and has a maximum absorption wavelength of about 760 nm to about 810 nm, the second cyanine dye includes a heptamethine cyanine dye, is configured to absorb light having a wavelength in a range of about 850 nm to about 950 nm, and has a maximum absorption wavelength of about 870 nm to about 920 nm, and the third cyanine dye includes a heptamethine cyanine dye, is configured to absorb light having a wavelength in a range of about 950 nm to about 1100 nm, and has a maximum absorption wavelength of about 1000 nm to about 1100 nm.

### BRIEF DESCRIPTION OF THE DRAWINGS

Embodiments of the inventive concept will be more clearly understood from the following detailed description taken in conjunction with the accompanying drawings in which:

FIG. 1 is a graph showing light absorption characteristics of an example composition for a near-infrared light-blocking filter according to some embodiments;

FIG. 2 to FIG. 4 are graphs showing light absorption characteristics of an example composition for a near-infrared light-blocking filter according to some embodiments;

FIG. 5 is a plan view illustrating an image sensor according to some embodiments;

FIG. 6 is a cross-sectional view taken along line A-A′ in FIG. 5;

FIG. 7 is a plan view illustrating an image sensor according to some embodiments;

FIG. 8 is a plan view illustrating an image sensor according to some embodiments;

FIG. 9 is a cross-sectional view taken along line A-A′ in FIG. 8; and

FIG. 10 is a cross-sectional view illustrating an image sensor according to some embodiments.

### DETAILED DESCRIPTION OF THE EMBODIMENTS

Hereinafter, embodiments are described in detail with reference to the accompanying drawings.

Embodiments include a composition for a near-infrared light-blocking filter employed in an image sensor, a near-infrared light-blocking filter manufactured using the composition for a near-infrared light-blocking filter, and an image sensor including the near-infrared light-blocking filter.

The composition for near-infrared light-blocking filter according to some embodiments may include a mixture of a first cyanine dye, a second cyanine dye, and a third cyanine dye.

In some embodiments, the first cyanine dye may be expressed by General Formula 1 below.

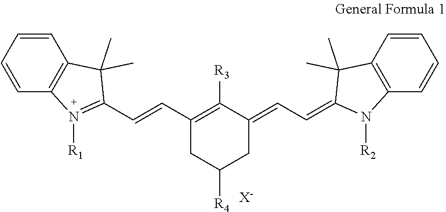

In General Formula 1, R₁ and R₂ may be each independently a linear or branched alkyl group having a carbon number of 6 to 12. R₃ may be at least one of a halogen element, a phenol group, a p-hydroxybenzoic acid group, a methylparaben group, a methyl p-aminobenzoate group, a p-aminobenzoic acid group, an aniline group, a benzenesulfinic acid group, and a diphenylamine group. R₄ may be at least one of a n-butyl group, a sec-butyl group, an iso-butyl group, a tert-butyl group, a phenyl group, a benzyl group, a tert-butylphenyl group, a cyclopropyl group, a cyclobutyl group, a cyclopentyl group, a cyclohexyl group, a cyclohexenyl group, a cycloheptyl group, a cyclooctyl group, a methoxyl group, an ethoxyl group, and a propoxyl group. X may be a non-metallic element. For example, X may be at least one of a halogen element, phosphoric acid, hexafluorophosphate, perchlorate, tetrafluoroborate, p-toluenesulfonate, bis(trifluoromethanesulfonyl)azanide (TFSI), and tetrakis[3,5-bis(trifluoromethyl)phenyl]borate (BARF).

In some embodiments, the second cyanine dye may be expressed by General Formula 2 below.

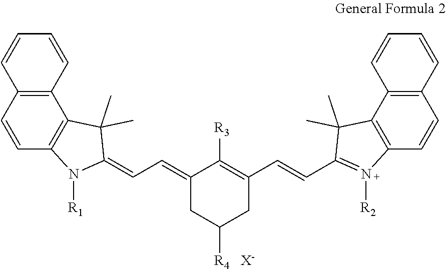

In General Formula 2, R₁ and R₂ may be each independently a linear or branched alkyl group having a carbon number of 6 to 12. R₃ may be at least one of a halogen element, a phenol group, a p-hydroxybenzoic acid group, a methylparaben group, a methyl p-aminobenzoate group, a p-aminobenzoic acid group, an aniline group, a benzenesulfinic acid group, and a diphenylamine group. R₄ may be at least one of a n-butyl group, a sec-butyl group, an iso-butyl group, a tert-butyl group, a phenyl group, a benzyl group, a tert-butylphenyl group, a cyclopropyl group, a cyclobutyl group, a cyclopentyl group, a cyclohexyl group, a cyclohexenyl group, a cycloheptyl group, a cyclooctyl group, a methoxyl group, an ethoxyl group, and a propoxyl group. X may be a non-metallic element. For example, X may be at least one of a halogen element, phosphoric acid, hexafluorophosphate, perchlorate, tetrafluoroborate, p-toluenesulfonate, TFSI, and BARF.

In some embodiments, the third cyanine dye may be expressed by General Formula 3 or General Formula 4 below.

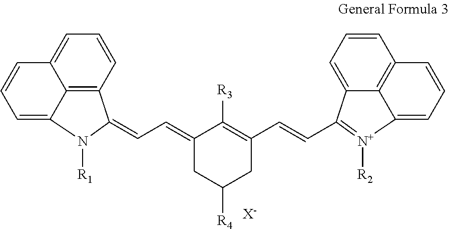

In General Formula 3, R₁ and R₂ may be each independently a linear or branched alkyl group having a carbon number of 6 to 12. R₃ may be at least one of a halogen element, a phenol group, a p-hydroxybenzoic acid group, a methylparaben group, a methyl p-aminobenzoate group, a p-aminobenzoic acid group, an aniline group, a benzenesulfinic acid group, and a diphenylamine group. R₄ may be at least one of a n-butyl group, a sec-butyl group, an iso-butyl group, a tert-butyl group, a phenyl group, a benzyl group, a tert-butylphenyl group, a cyclopropyl group, a cyclobutyl group, a cyclopentyl group, a cyclohexyl group, a cyclohexenyl group, a cycloheptyl group, a cyclooctyl group, a methoxyl group, an ethoxyl group, and a propoxyl group. X may be a non-metallic element. For example, X may be at least one of a halogen element, phosphoric acid, hexafluorophosphate, perchlorate, tetrafluoroborate, p-toluenesulfonate, TFSI, and BARF.

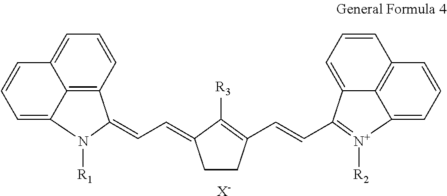

In General Formula 4, R₁ and R₂ may be each independently a linear or branched alkyl group having a carbon number of 6 to 12. R₃ may be at least one of a halogen element, a phenol group, a p-hydroxybenzoic acid group, a methylparaben group, a methyl p-aminobenzoate group, a p-aminobenzoic acid group, an aniline group, a benzenesulfinic acid group, and a diphenylamine group. X may be a non-metallic element. For example, X may be at least one of a halogen element, phosphoric acid, hexafluorophosphate, perchlorate, tetrafluoroborate, p-toluenesulfonate, TFSI, and BARF.

In some embodiments, the composition for a near-infrared light-blocking filter may include a binder solution, a first cyanine dye, a second dye, and a third cyanine dye, which are contained in the binder solution at a predetermined ratio.

In some embodiments, the binder solution may include a polysulfone polymer or cycloolefin polymer contained in a chloroform or dichloromethane solvent. In some embodiments, the binder solution may include at least one of polyarylene ether sulfone, polyether ether sulfone, polyether sulfone, polyimide, polyimidazole, polybenzimidazole, polyetherbenzimidazole, polyarylene ether ketone, polyether ether ketone, polyetherketone, polyetherketoneketone, and polystyrene.

In some embodiments, the first cyanine dye, the second cyanine dye, and the third cyanine dye may be included in a weight ratio of a:b:c in the composition for a near-infrared light-blocking filter, wherein a may be about 0.1 to about 0.9, b may be about 0.2 to about 1.0, and c may be about 0.6 to about 1.4. In some embodiments, the first cyanine dye, the second cyanine dye, and the third cyanine dye may be included in a weight ratio of a:b:c in the composition for a near-infrared light-blocking filter, wherein a may be about 0.4 to about 0.6, b may be about 0.5 to about 0.7, and c may be about 0.9 to about 1.1.

In some embodiments, in the composition for a near-infrared light-blocking filter, the first cyanine dye, the second cyanine dye, and the third cyanine dye may be included in molar amounts of a1:b1:c1 in the binder solution. For example, in the binder solution, the first cyanine dye may be included in an amount of about 0.0005 mmol to about 0.0045 mmol (millimole) (for example, a1 may be in a range of about 0.0005 mmol to about 0.0045 mmol), the second cyanine dye may be included in an amount of about 0.001 mmol to about 0.005 mmol (for example, b1 may be in a range of about 0.001 mmol to about 0.005 mmol), and the third cyanine dye may be included in an amount of about 0.003 mmol to about 0.007 mmol (for example, c1 may be in a range of about 0.003 mmol to about 0.007 mmol).

In some embodiments, a weight ratio of the first cyanine dye, the second cyanine dye, and the third cyanine dye included in the composition for the near-infrared light-blocking filter may be in a range in which a transmittance for near-infrared light is minimized while a transmittance for visible light is maximized.

In some embodiments, a near-infrared light-blocking filter manufactured using the composition for a near-infrared light-blocking filter may have a first average transmittance for light having a wavelength of about 700 to about 1100 nm, or any range therein (for example, for near-infrared light), and the first average transmittance may be in a range of about 0% to about 30%, or any range therein. In some embodiments, the first average transmittance may be in a range of about 0% to about 10%.

In some embodiments, the near-infrared light-blocking filter may have a second average transmittance for light having a wavelength of about 400 nm to about 700 nm, or any range therein (for example, for visible light), and the second average transmittance may be in a range of about 60% to about 100%, or any range therein. In some embodiments, the second average transmittance may be in a range of about 80% to about 100%.

In some embodiments, the first cyanine dye may be configured to absorb light having a wavelength in a range of about 750 nm to about 850 nm, or any range therein, and the first cyanine dye may have a maximum absorption wavelength of about 760 nm to about 810 nm, or any range therein. In some embodiments, the second cyanine dye may be configured to absorb light having a wavelength in a range of about 850 nm to about 950 nm, or any range therein, and the second cyanine dye may have a maximum absorption wavelength of about 870 nm to about 920 nm, or any range therein. In some embodiments, the third cyanine dye may be configured to absorb light having a wavelength in a range of about 950 nm to about 1100 nm, or any range therein, and the third cyanine dye may have a maximum absorption wavelength of about 1000 nm to about 1100 nm, or any range therein. Since the composition for a near-infrared light-blocking filter includes the first cyanine dye, the second cyanine dye, and the third cyanine dye in a weight ratio of a:b:c, the near-infrared light filter formed from the composition for a near-infrared light-blocking filter may have excellent visible light transmission characteristics in addition to excellent near-infrared light-blocking characteristics (or absorption characteristics).

Hereinafter, a synthetic method of a composition for a near-infrared light-blocking filter according to some embodiments will be described.

### Synthetic Method of First Cyanine Dye

The first cyanine dye included in the composition for a near-infrared light-blocking filter according to some embodiments may be represented by General Formula 1 below.

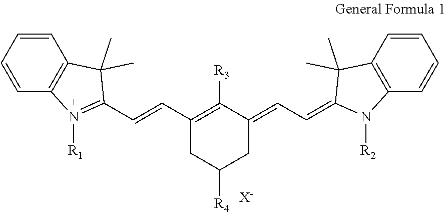

In General Formula 1, R₁ and R₂ may be each independently a linear or branched alkyl group having a carbon number of 6 to 12. R₃ may be at least one of a halogen element, a phenol group, a p-hydroxybenzoic acid group, a methylparaben group, a methyl p-aminobenzoate group, a p-aminobenzoic acid group, an aniline group, a benzenesulfinic acid group, and a diphenylamine group. R₄ may be at least one of a n-butyl group, a sec-butyl group, an iso-butyl group, a tert-butyl group, a phenyl group, a benzyl group, a tert-butylphenyl group, a cyclopropyl group, a cyclobutyl group, a cyclopentyl group, a cyclohexyl group, a cyclohexenyl group, a cycloheptyl group, a cyclooctyl group, a methoxyl group, an ethoxyl group, and a propoxyl group. X may be a non-metallic element. For example, X may be at least one of a halogen element, phosphoric acid, hexafluorophosphate, perchlorate, tetrafluoroborate, p-toluenesulfonate, TFSI, and BARF. In some embodiments, X may be TFSI and/or tBARF.

In some embodiments, R₁ and R₂ in General Formula 1 may have a relatively long alkyl group having a carbon number of 6 to 12, and thus the first cyanine dye may have an excellent solubility in the binding solution. In some embodiments, in General Formula 1, R₄ includes a substituent having characteristics that impart a steric hindrance, and thus, when the first cyanine dye is dissolved in the binding solution, aggregation of the first cyanine dye molecules may be prevented. In some embodiments, in General Formula 1, X⁻ may be a counter anion, and/or may be a non-metallic ion. In some embodiments, X may be a non-metallic ion having a large molecular weight, such as TFSI and BARF, and thus the first cyanine dye may have improved solubility and durability. In some embodiments, the first cyanine dye may be configured to absorb light having a wavelength in a range of about 750 nm to about 850 nm, and the first cyanine dye may have a maximum absorption wavelength of about 760 nm to about 810 nm.

The first cyanine dye expressed by General Formula 1 may be synthesized by the following exemplary synthetic method.

First, a 2,3,3-trimethylindolenine derivative may be synthesized. As represented by Step 1-1 below, 1-hexyl-2,3,3-trimethyl-3H-indol-1-ium is synthesized by adding 2,3,3-trimethylindolenine to an acetonitrile solution, adding alkyl iodide, and performing a reation at 100° C. for 12 hours.

### Step 1-1

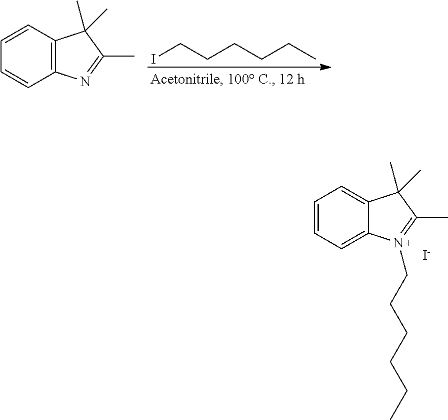

Then, an anilinium salt may be synthesized. As represented by Step 1-2 below, dimethylformamide is added to phosphoryl chloride (POCl₃) to perform a reaction for 30 minutes at 0° C. and then the reaction product is refluxed for 30 minutes in a cyclohexanone solution. Then, N-((E)-((E)-2-chloro-3-((phenylamino)methylene)cyclohex-1-en-1-yl)methylene)benzenaminium may be synthesized by preforming a reaction at room temperature for 1 hour by adding aniline and ethanol.

### Step 1-2

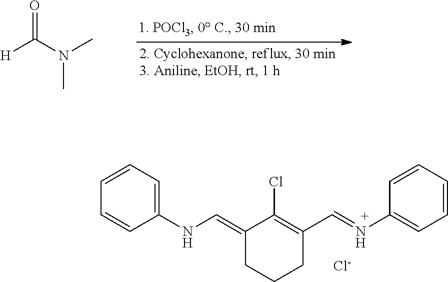

Then, a heptamethine cyanine dye may be synthesized by a coupling reaction. As represented by Step 1-3 below, a heptamethine cyanine dye may be synthesized by adding the 2-3-3 trimethylindolenine derivative formed in Step 1-2 (for example, 1-hexyl-2,3,3-trimethyl-3H-indol-1-rium) and the anilinium salt formed in Step 1-2 (for example, N-((E)-((E)-2-chloro-3-((phenylamino)methylene)cyclohex-1-en-1-yl)methylene)benzenaminium to sodium acetate and ethanol and refluxing for 12 hours.

### Step 1-3

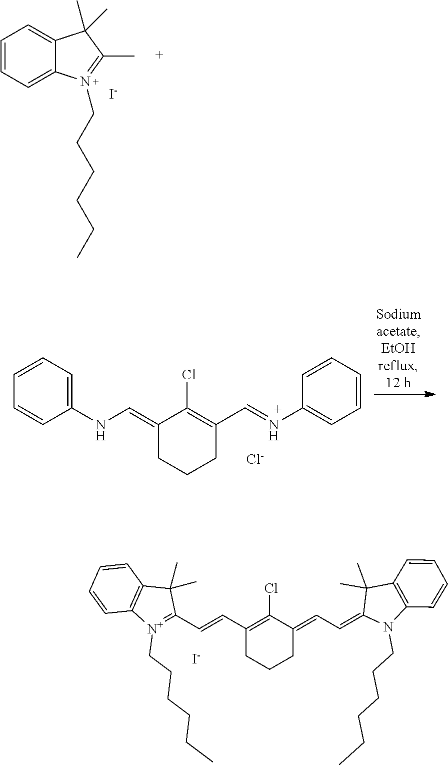 [SMILES: CCCCCC[N+]1=C(C)C(C)(C)c2ccccc21 ; [I-] ; ClC1=C(/C=[NH+]/c2ccccc2)CCC/C1=C\Nc1ccccc1 ; [Cl-] ; CCCCCCN1/C(=C/C=C2\CCCC(/C=C/C3=[N+](CCCCCC)c4ccccc4C3(C)C)=C2Cl)C(C)(C)c2ccccc21 ; [I-]]

In some embodiments, a heptamethine cyanine dye synthesized through Steps 1-1, 1-2, and 1-3 above may be 2-((E)-2-((E)-2-chloro-3-(2-((E)-1-hexyl-3,3-dimethylindolin-2-ylidene) ethylidene)cyclohex-1-en-1-yl)vinyl)-1-hexyl-3,3-dimethyl-3H-indol-1-ium.

Thereafter, as represented by Step 1-4 below, 1-hexyl-2-((E)-2-((E)-3-(2-((E)-1-hexyl-3,3-dimethylindolin-2-ylidene) ethylidene)-2-phenoxycyclohex-1-en-1-yl)vinyl)-3,3-dimethyl-3H-indol-1-ium may be synthesized by adding the heptamethine cyanine dye synthesized in Step 1-3 to a solution of sodium hydride (NaH) and dimethylformamide (DMF) and performing a reaction by adding phenol at room temperature.

### Step 1-4

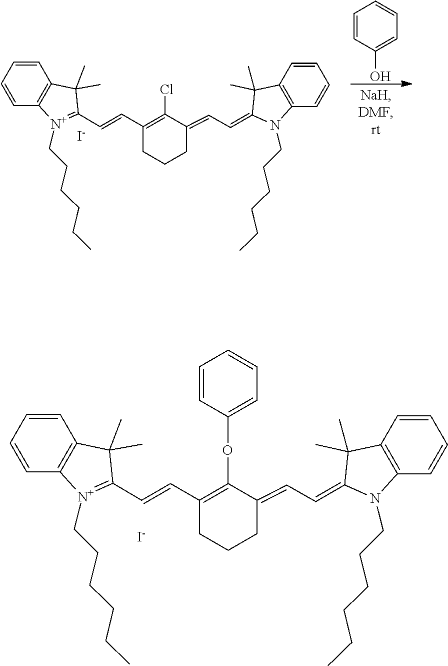 [SMILES: CCCCCCN1/C(=C/C=C2\CCCC(/C=C/C3=[N+](CCCCCC)c4ccccc4C3(C)C)=C2Cl)C(C)(C)c2ccccc21 ; [I-] ; Oc1ccccc1 ; CCCCCCN1/C(=C/C=C2\CCCC(/C=C/C3=[N+](CCCCCC)c4ccccc4C3(C)C)=C2Oc2ccccc2)C(C)(C)c2ccccc21 ; [I-]]

Thereafter, an anion substitution may be performed. As represented by Step 1-5 below, a first cyanine dye may be synthesized at room temperature by adding the heptamethine cyanine dye synthesized in Step 1-4 to an acetone solution and adding a BARF anion.

### Step 1-5

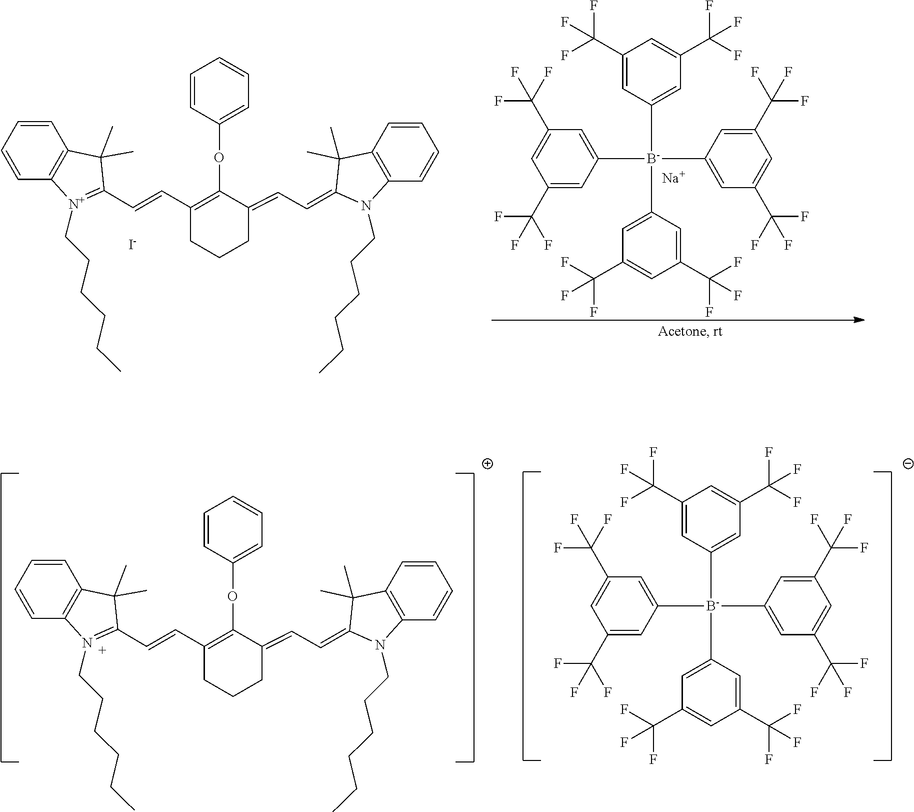

### Synthetic Method of Second Cyanine Dye

The second cyanine dye contained in the composition for a near-infrared light-blocking filter according to some embodiments may be expressed by General Formula 2 below.

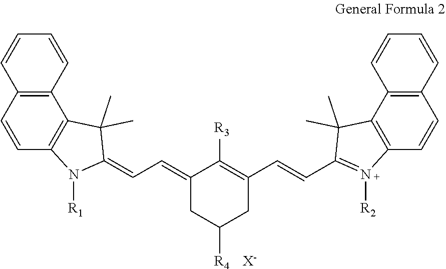

In General Formula 2, R₁ and R₂ may be each independently a linear or branched alkyl group having a carbon number of 6 to 12. R₃ may be at least one of a halogen element, a phenol group, a p-hydroxybenzoic acid group, a methylparaben group, a methyl p-aminobenzoate group, a p-aminobenzoic acid group, an aniline group, a benzenesulfinic acid group, and a diphenylamine group. R₄ may be at least one of a n-butyl group, a sec-butyl group, an iso-butyl group, a tert-butyl group, a phenyl group, a benzyl group, a tert-butylphenyl group, a cyclopropyl group, a cyclobutyl group, a cyclopentyl group, a cyclohexyl group, a cyclohexenyl group, a cycloheptyl group, a cyclooctyl group, a methoxyl group, an ethoxyl group, and a propoxyl group. X may be a non-metallic element. For example, X may be at least one of a halogen element, phosphoric acid, hexafluorophosphate, perchlorate, tetrafluoroborate, p-toluenesulfonate, TFSI, and BARF.

In some embodiments, R₁ and R₂ in General Formula 2 may have a relatively long alkyl group having a carbon number of 6 to 12, and thus the second cyanine dye may have an excellent solubility in the binding solution. In some embodiments, in General Formula 2, R₄ includes a substituent having characteristics that impart a steric hindrance, and thus, when the second cyanine dye is dissolved in the binding solution, aggregation of the second cyanine dye molecules may be prevented. In some embodiments, in General Formula 2, X⁻ may be a counter anion, and/or may be a non-metallic ion. In some embodiments, X may be a non-metallic ion having a large molecular weight, such as TFSI and BARF, and thus the second cyanine dye may have improved solubility and durability. In some embodiments, the second cyanine dye may be configured to absorb light having a wavelength in a range of about 850 to about 950 nm, and the second cyanine dye may have a maximum absorption wavelength of about 870 nm to about 920 nm.

The second cyanine dye expressed by General Formula 2 may be synthesized by the following exemplary synthetic method.

First a commercial dye (IR-813) derivative may be synthesized. As represented by Step 2-1,1,1,3-trimethyl-2-((E)-2-((E)-2-(phenylsulfonyl)-3-((E)-2-(1,1,3-trimethyl-1,3-dihydro-2H-benzol[e]indol-2-ylidene)ethylidene)cyclohex-1-en-1-yl)vinyl)-1H-benzol[e]indol-3-iumindol-1-ium 4-methylbenzenesulfonate may be synthesized in a solution including a sodium cation and a benzenesulfonic acid anion from IR-813 which is a commercial dye.

### Step 2-1

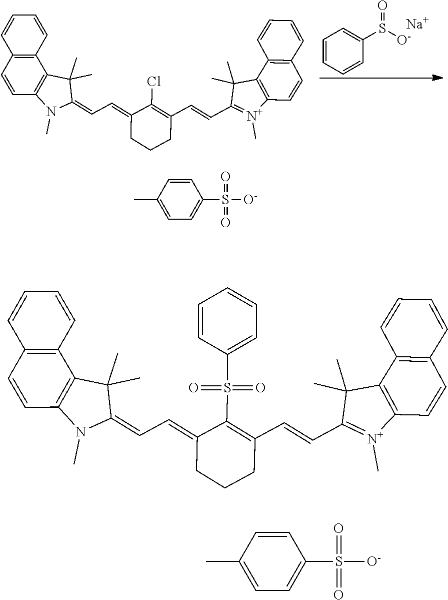 [SMILES: CN1/C(=C/C=C2\CCCC(/C=C/C3=[N+](C)c4ccc5ccccc5c4C3(C)C)=C2Cl)C(C)(C)c2c1ccc1ccccc21 ; O=S([O-])c1ccccc1 ; [Na+] ; Cc1ccc(S(=O)(=O)[O-])cc1 ; CN1/C(=C/C=C2\CCCC(/C=C/C3=[N+](C)c4ccc5ccccc5c4C3(C)C)=C2S(=O)(=O)c2ccccc2)C(C)(C)c2c1ccc1ccccc21 ; Cc1ccc(S(=O)(=O)[O-])cc1]

Thereafter, an anion substitution may be performed. As represented by Step 2-2 below, the second cyanine dye may be synthesized at room temperature by adding the commercial dye derivative synthesized in Step 2-1 to an acetone solution and adding a BARF anion.

### Step 2-2

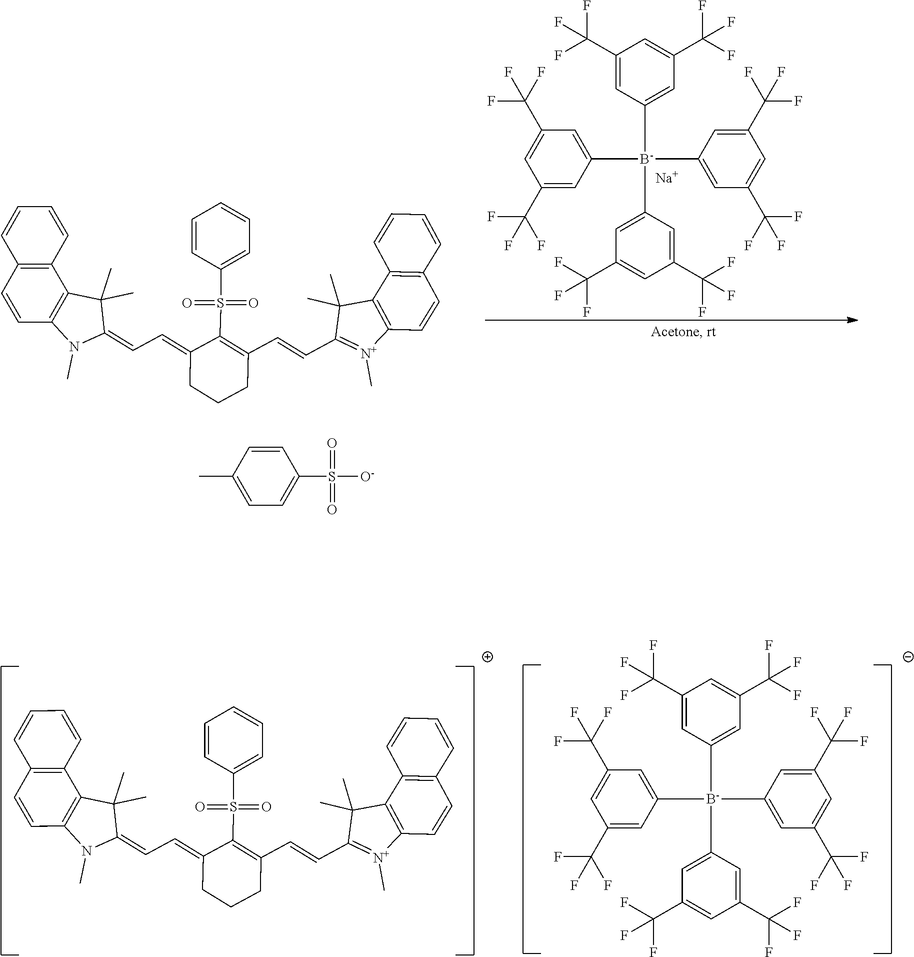

### Synthetic Method of Third Cyanine Dye

The third dye contained in the composition for a near-infrared light-blocking filter according to some embodiments may be expressed by General Formula 3 below.

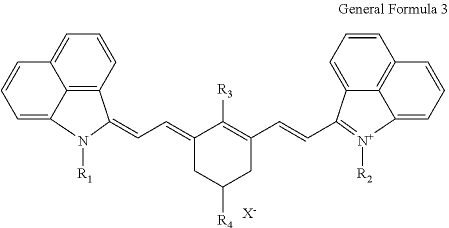

In General Formula 3, R₁ and R₂ may be each independently a linear or branched alkyl group having a carbon number of 6 to 12. R₃ may be at least one of a halogen element, a phenol group, a p-hydroxybenzoic acid group, a methylparaben group, a methyl p-aminobenzoate group, a p-aminobenzoic acid group, an aniline group, a benzenesulfinic acid group, and a diphenylamine group. R₄ may be at least one of a n-butyl group, a sec-butyl group, an iso-butyl group, a tert-butyl group, a phenyl group, a benzyl group, a tert-butylphenyl group, a cyclopropyl group, a cyclobutyl group, a cyclopentyl group, a cyclohexyl group, a cyclohexenyl group, a cycloheptyl group, a cyclooctyl group, a methoxyl group, an ethoxyl group, and a propoxyl group. X may be a non-metallic element. For example, X may be at least one of a halogen element, phosphoric acid, hexafluorophosphate, perchlorate, tetrafluoroborate, p-toluenesulfonate, TFSI, and BARF.

In some embodiments, in General Formula 3, R₁ and R₂ may have a relatively long alkyl group having a carbon number of 6 to 12, and thus the third cyanine dye may have excellent solubility in a binding solution. In some embodiments, in General Formula 3, R₄ includes a substituent having characteristics that impart a steric hindrance, and thus, when the third cyanine dye is dissolved in the binding solution, aggregation of the third cyanine dye molecules may be prevented. In some embodiments, in General Formula 3, X⁻ may be a counter anion, and/or may be a non-metallic ion. In some embodiments, X may be a non-metallic ion having a large molecular weight, such as TFSI and BARF, and thus the third cyanine dye may have improved solubility and durability. In some embodiments, the third cyanine dye may be configured to absorb light having a wavelength in a range of about 950 nm to about 1100 nm, and the third cyanine dye may have a maximum absorption wavelength of about 1000 nm to about 1100 nm.

The third cyanine dye expressed by General Formula 3 may be synthesized by the following exemplary synthetic method.

First, a benzo[c,d]indolium derivative may be synthesized. As represented by Step 3-1 below, 1-decylbenzo[c,d]indol-2(1H)-one is synthesized by adding benzo[c,d]indol-2(1H)-one to o-dichlorobenzene, and adding CH₃(CH₂)₉I, an aqueous solution of 45% NaOH, and a 18-crown-6 material together. Then, methyl magnesium iodide, and ether are added, the mixture is maintained at −5° C. for a predetermined time and then maintained at 35° C. for a predetermined time. Then, 1-decyl-2-methylbenzo[cd]indol-1-ium perchlorate may be synthesized by adding an aqueous solution of 20% HClO₄ and performing a reaction at 0° C.

### Step 3-1

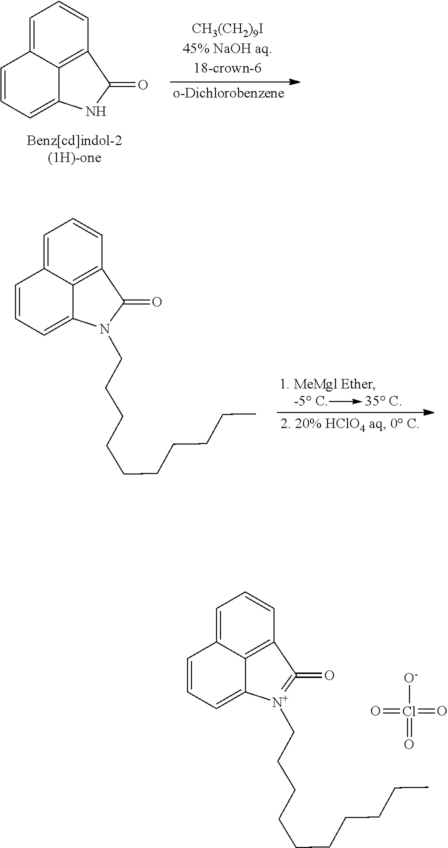

Then, an anilinium salt may be synthesized. As represented by Step 3-2 below, dimethylformamide is added to phosphoryl chloride (POCl₃), and the mixture is reacted for 30 minutes at 0° C. and then refluxed for 30 minutes in a cyclohexanone solution. Then, N-((E)-((E)-2-chloro-3-((phenylamino)methylene)cyclohex-1-en-1-yl)methylene)benzenaminium may be synthesized by performing a reaction by adding aniline and ethanol at room temperature for 1 hour.

### Step 3-2

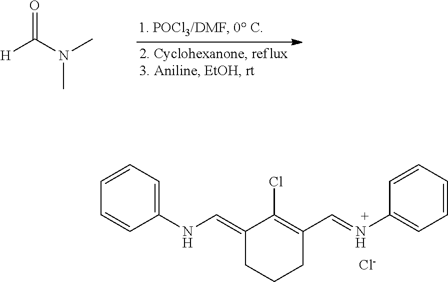

Thereafter, a heptamethine cyanine dye may be synthesized by a coupling reaction. As represented by Step 3-3 below, a heptamethine cyanine dye may be synthesized by adding the benzo[c,d]indolium derivative formed in Step 3-1 and the anilinium salt to acetic anhydride and sodium acetate formed in Step 3-2. In some embodiments, the heptamethine cyanine dye synthesized by steps 3-1, 3-2, and 3-3 may be 2-((E)-2-((E)-2-chloro-3-((E)-2-(1-decylbenzo[cd]indol-2(1H)-ylidene)ethylidene)cyclohex-1-en-1-yl)vinyl)-1-decylbenzo[cd]indol-1-ium perchlorate.

### Step 3-3

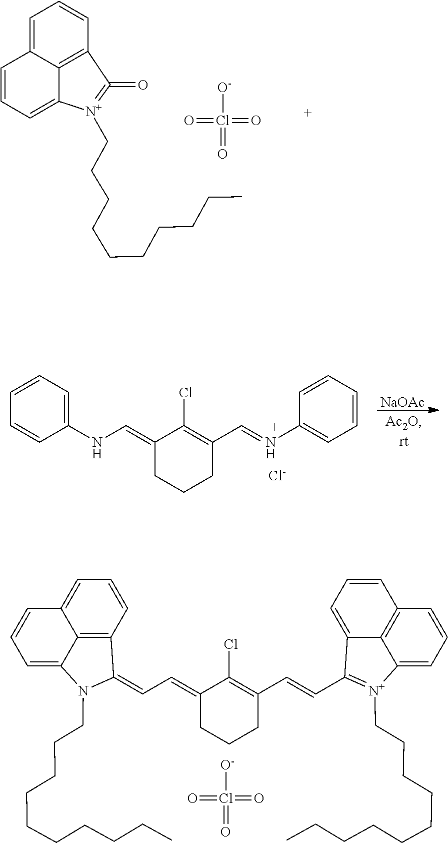

Thereafter, an anion substitution may be performed. As represented by Step 3-4 below, the third cyanine dye may be synthesized. performing a reaction at room temperature by adding the heptamethine cyanine dye synthesized in Step 3-3 to a solution of NaBARF and a dichloromethane (DCM)/acetone.

### Step 3-4

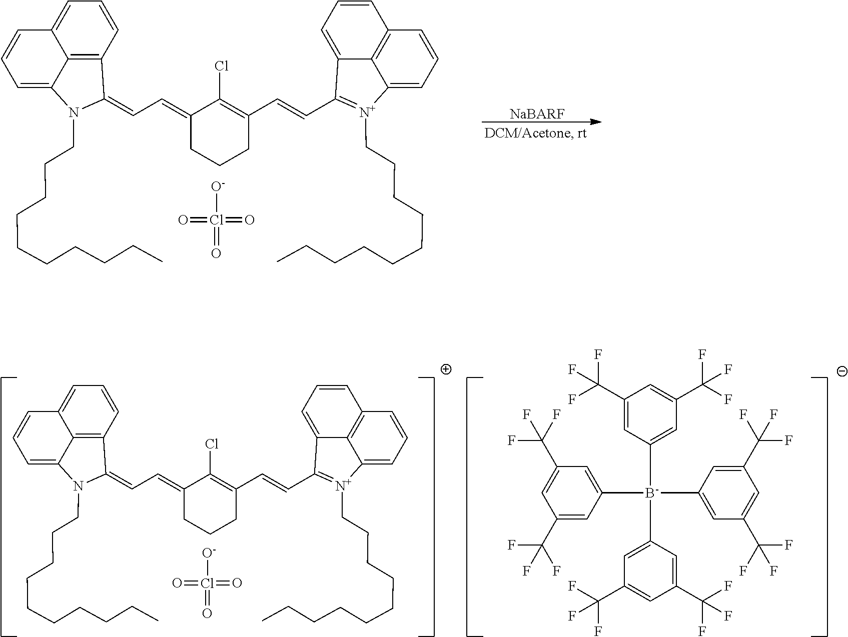

### Synthetic Method of Fourth Cyanine Dye

The third dye included in the composition for a near-infrared light-blocking filter according to some embodiments may be expressed by General Formula 4 below.

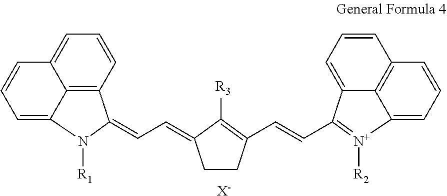

In General Formula 4, R₁ and R₂ may be each independently a linear or branched alkyl group having a carbon number of 6 to 12. R₃ may be at least one of a halogen element, a phenol group, a p-hydroxybenzoic acid group, a methylparaben group, a methyl p-aminobenzoate group, a p-aminobenzoic acid group, an aniline group, a benzenesulfinic acid group, and a diphenylamine group. X may be a non-metallic element. For example, X may be at least one of a halogen element, phosphoric acid, hexafluorophosphate, perchlorate, tetrafluoroborate, p-toluenesulfonate, TFSI, and tBARF.

In some embodiments, R₁ and R₂ in General Formula 4 may have a relatively long alkyl group having a carbon number of 6 to 12, and thus the third cyanine dye may have excellent solubility in a binding solution. In some embodiments, in General Formula 4, X⁻ may be a counter anion, and/or may be a non-metallic ion. In some embodiments, X may be a non-metallic ion having a large molecular weight, such as TFSI and BARF, and thus the third cyanine dye may have improved solubility and durability. In some embodiments, the third cyanine dye may be configured to absorb light having a wavelength in a range of about 950 nm to about 1100 nm, and the third cyanine dye may have a maximum absorption wavelength of about 1000 nm to about 1100 nm.

The third cyanine dye expressed by General Formula 4 may be synthesized by the following exemplary synthetic method.

First, a benzo[c,d]indolium derivative may be synthesized. As represented by Step 3-1 below, 1-decylbenzo[c,d]indol-2(1H)-one is synthesized by adding benzo[c,d]indol-2(1H)-one to o-dichlorobenzene and adding CH₃(CH₂)₉I, an aqueous solution of 45% NaOH, and a 18-crown-6 material together. Then, methyl magnesium iodide, and ether are added, the mixture is maintained at −5° C. for a predetermined time, and then maintained at 35° C. for a predetermined time. Then, 1-decyl-2-methylbenzo[cd]indol-1-ium perchlorate may be synthesized by adding an aqueous solution of 20% HClO₄ and performing a reaction at 0° C.

### Step 4-1

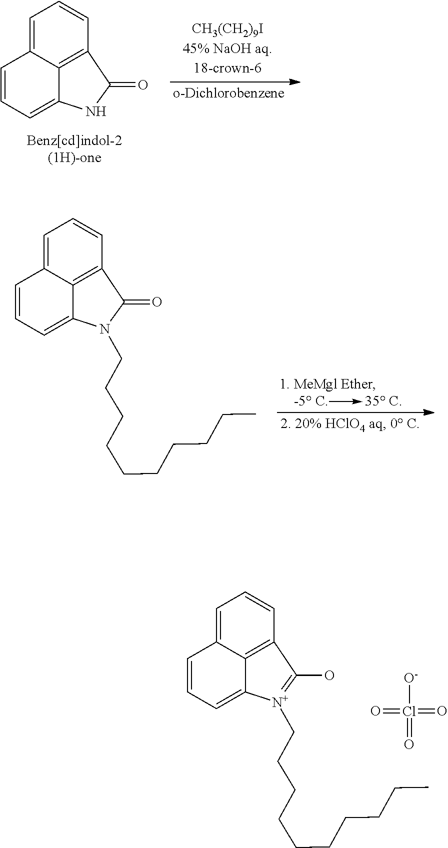

Then, an anilinium salt may be synthesized. As represented by Step 4-2 below, dimethylformamide is added to phosphoryl chloride (POCl₃), and the mixture is reacted for 30 minutes at 0° C. and then refluxed for 30 minutes in a cyclohexanone solution. Then, N-((E)-((E)-2-chloro-3-((phenylamino)methylene)cyclopent-1-en-1-yl)methylene)benzenaminium may be synthesized by performing a reaction at room temperature for 1 hour by adding aniline and ethanol.

### Step 4-2

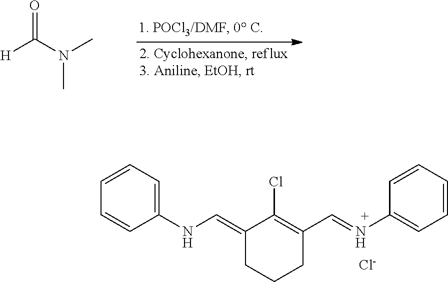

Then, a heptamethine cyanine dye may be synthesized by a coupling reaction. As represented by Step 4-3 below, a heptamethine cyanine dye may be synthesized by adding the benzo[c,d]indolium derivative formed in Step 4-1 and the anilinium salt formed in Step 4-2 to acetic anhydride and sodium acetate. In some embodiments, the heptamethine cyanine dye synthesized by steps 4-1, 4-2, and 4-3 may be 2-((E)-2-((E)-2-chloro-3-((E)-2-(1-decylbenzo[cd]indol-2(1H)-ylidene)ethylidene)cyclopent-1-en-1-yl)vinyl)-1-decylbenzo[cd]indol-1-ium perchlorate.

### Step 4-3

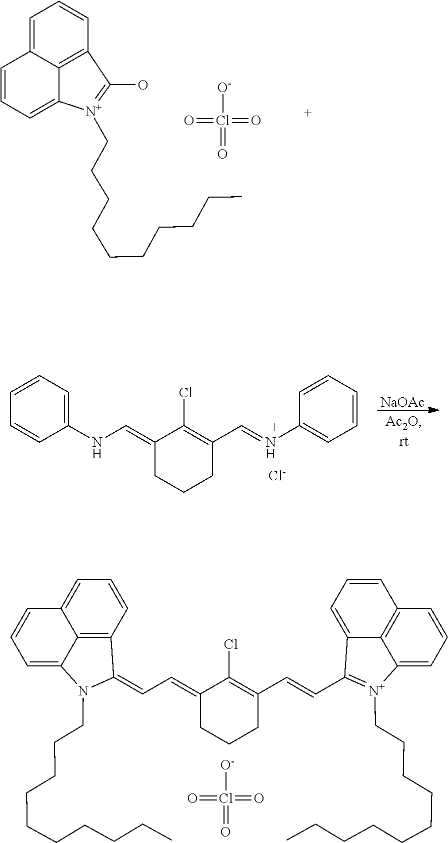

Thereafter, an anion substitution may be performed. As represented by Step 4-4 below, a third cyanine dye may be synthesized by performing a reaction at room temperature by adding the heptamethine cyanine dye synthesized in Step 4-3 to a solution of NaBARF and dichloromethane (DCM)/acetone.

### Step 4-4

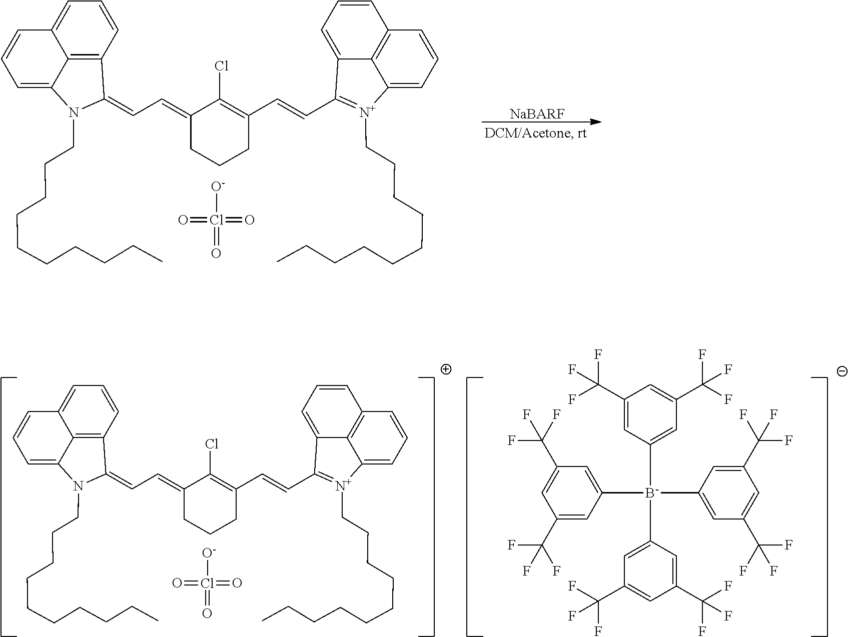

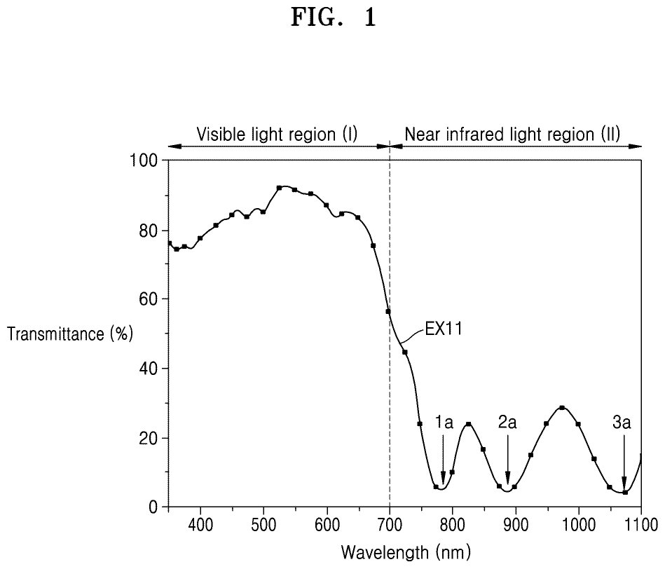

FIG. 1 is a graph showing light absorption characteristics of a composition for a near-infrared light-blocking filter according to some embodiments.

In FIG. 1, light absorption data in a wavelength region of about 350 nm to about 1100 nm, of the near-infrared light-blocking filter according to Experimental Example 11 (EX11) is illustrated. For forming the near-infrared light-blocking filter according to Experimental Example 11 (EX11), the first cyanine dye, the second cyanine dye, and the third cyanine dye were mixed at a ratio of 0.6:0.5:1, the mixture was spin-coated on a transparent substrate, and the substrate was dried to obtain a near-infrared light-blocking filter in a film state. The first cyanine dye included the heptamethine cyanine dye expressed by General Formula 1, which was obtained by the above-described synthetic method, the second cyanine dye included the heptamethine cyanine dye expressed by General Formula 2, which was obtained by the above-described synthetic method, and the third cyanine dye included the heptamethine cyanine dye expressed by General Formula 4, which was obtained by the above-described synthetic method. The near-infrared light-blocking filter was formed to have a thickness of about 1.5 micrometers.

As illustrated in FIG. 1, the near-infrared light-blocking filter according to Experimental Example 11 (EX11) exhibited a transmittance of at least 60% and exhibited an average transmittance of at least 80% in a visible light region (I), for example in a light region having a wavelength of at most 700 nm. In addition, the near-infrared light-blocking filter according to Experimental Example 11(EX11) exhibited an average transmittance of about 0% to about 30% in an infrared light region (II), for example in a light region having a wavelength of about 700 nm to about 1100 nm. Particularly, a maximum transmittance did not exceed approximately 30% in a wavelength region of about 750 nm to about 1100 nm, and thus the near-infrared light-blocking filter according to Experimental Example 11 (EX11) exhibited the average transmittance of about 0% to about 10% in a wavelength region of about 750 nm to about 1100 nm.

As illustrated in FIG. 1, the near-infrared light-blocking filter according to Experimental Example 11 (EX11) in a near infrared light region (II) may exhibit three peak values, each having an inflection point of transmittance, a first peak 1a is observed at a wavelength of approximately 780 nm, a second peak 2a is observed at a wavelength of approximately 890 nm, and a third peak 3a is observed at a wavelength of approximately 1070 nm.

For example, in a region of about 750 nm to about 850 nm, the near-infrared light-blocking filter according to Experimental Example 11 (EX11) exhibits a lowest transmittance at the first peak 1a observed at a wavelength of approximately 780 nm. The transmittance peak may be due to the first cyanine dye expressed by General Formula 1, and the first peak 1a may correspond to maximum absorption wavelength of the first cyanine dye.

For example, in a region of about 850 nm to about 950 nm, the near-infrared light-blocking filter according to Experimental Example 11 (EX11) exhibits a lowest transmittance at the second peak 2a observed at a wavelength of approximately 890 nm. The transmittance peak may be due to the second cyanine dye expressed by General Formula 2, and the second peak 2a may correspond to a maximum absorption wavelength of the second cyanine dye.

For example, in a region of about 950 nm to about 1100 nm, the near-infrared light-blocking filter according to Experimental Example 11 (EX11) exhibits a lowest transmittance at the third peak 3a observed at a wavelength of approximately 890 nm. The transmittance peak may be due to the third cyanine dye expressed by General Formula 4, and the third peak 3a may correspond to a maximum absorption wavelength of the third cyanine dye.

As illustrated in FIG. 1, the near-infrared light-blocking filter according to Experimental Example 11 (EX11) transmits light in the near infrared light region with a relatively low transmittance while transmitting light in the visible light region with a relatively high transmittance. In other words, it can be confirmed that the near-infrared light-blocking filter according to Experimental Example 11 (EX11) has absorbed light in the near infrared light region at a relatively high rate.

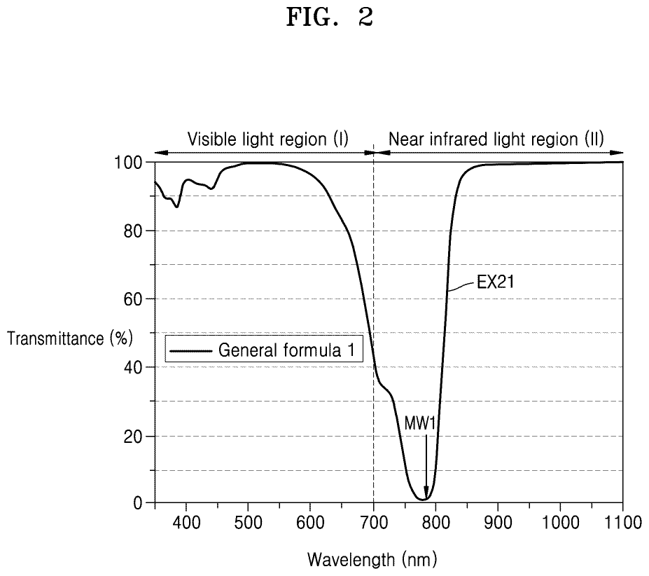

FIG. 2 to FIG. 4 are graphs showing light absorption characteristics of an example composition for a near-infrared light-blocking filter according to some embodiments.

In FIG. 2, light absorption data in a wavelength region of about 350 nm to about 1100 nm, of the near-infrared light-blocking filter according to Experimental Example 21 (EX21) is illustrated. For forming the near-infrared light-blocking filter according to Experimental Example 21 (EX21), only the first cyanine dye was added in a binder solution, the solution was spin-coated onto a transparent substrate, and the substrate was dried to obtain a near-infrared light-blocking filter in a film state. The first cyanine dye included the heptamethine cyanine dye expressed by General Formula 1, as obtained by the above-described synthetic method.

As illustrated in FIG. 2. the near-infrared light-blocking filter according to Experimental Example 21 (EX21) exhibited a transmittance of at least 60% and exhibited an average transmittance of at least 80% in a visible light region (I), for example, in a light region having a wavelength of at most 700 nm. In addition, the near-infrared light-blocking filter according to Experimental Example 21 (EX21) exhibited an average transmittance of about 0% to about 30% in a region of about 750 nm to about 850 nm of a near infrared light region (II). In particular, the near-infrared light-blocking filter according to Experimental Example 21 (EX21) has an absorption peak at a wavelength MW1 of about 780 nm, that is, has a lowest transmittance or a highest absorption value at a wavelength of about 780 nm.

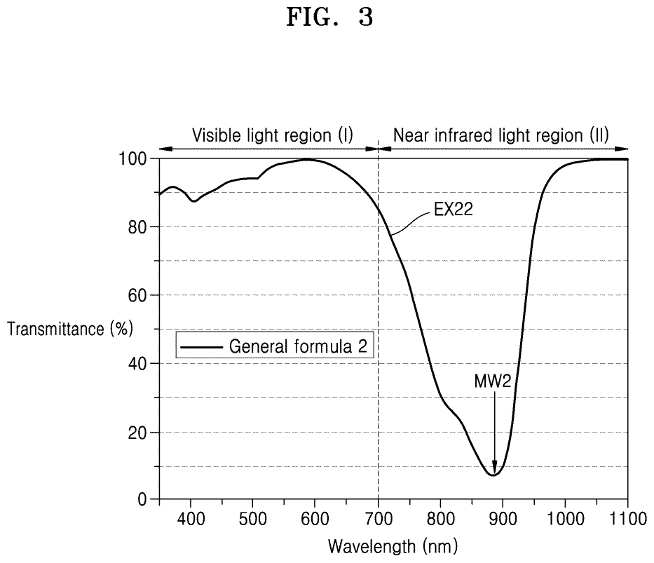

In FIG. 3, light absorption data in a wavelength region of about 350 nm to about 1100 nm, of the near-infrared light-blocking filter according to Experimental Example 22 (EX22) is illustrated. For forming the near-infrared light-blocking filter according to Experimental Example 22 (EX22), only the second cyanine dye was added in a binder solution, the solution was spin-coated onto a transparent substrate, and the substrate was dried to obtain a near-infrared light-blocking filter in a film state. The second cyanine dye included the heptamethine cyanine dye expressed by General Formula 2, as obtained by the above-described synthetic method.

As illustrated in FIG. 3. the near-infrared light-blocking filter according to Experimental Example 22 (EX22) exhibited a transmittance of at least 60% and exhibited an average transmittance of at least 80% in the visible light region (I), for example, in a light region having a wavelength of at most 700 nm. In addition, the near-infrared light-blocking filter according to Experimental Example 22 (EX22) exhibited an average transmittance of about 0% to about 30% in a region of about 850 nm to about 950 nm of a near infrared light region (II). In particular, the near-infrared light-blocking filter according to Experimental Example 22 (EX22) has an absorption peak at a wavelength MW2 of about 890 nm, that is, has a lowest transmittance or a highest absorption value at a wavelength of about 890 nm.

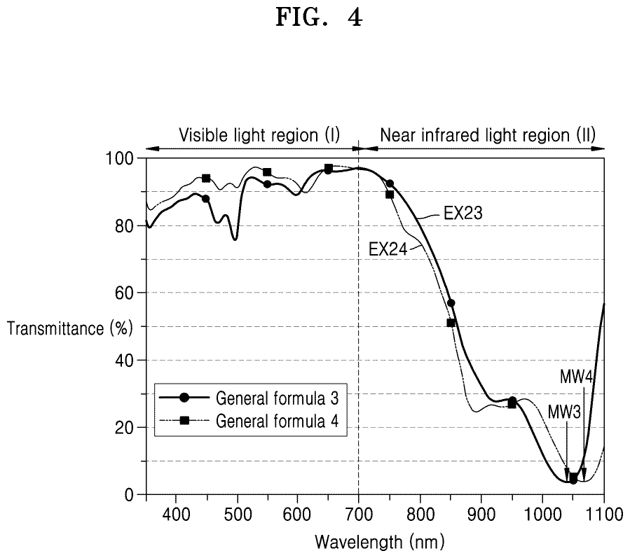

In FIG. 4, light absorption data in a wavelength region of about 350 nm to about 1100 nm, of the near-infrared light-blocking filter according to Experimental Example 23 (EX23) is illustrated. For forming the near-infrared light-blocking filter according to Experimental Example 23 (EX23) and Experimental Example 24 (EX24), only the third cyanine dye was added in a binder solution, the solution was spin-coated onto a transparent substrate, and the substrate was dried to obtain a near-infrared light-blocking filter in a film state. The third cyanine dye included in Experimental Example 23 (EX23) was a heptamethine cyanine dye expressed by General Formula 3, as obtained by the above-described synthetic method. The third cyanine dye included in Experimental Example 24 (EX24) was a heptamethine cyanine dye expressed by General Formula 4, as obtained by the above-described synthetic method.

As illustrated in FIG. 4. the near-infrared light-blocking filter according to Experimental Example 23 (EX23) and Experimental Example 24 (EX24) exhibited a transmittance of at least 60% and an average transmittance of at least 80% in the visible light region (I), for example, in a light region having a wavelength of at most 700 nm. In addition, the near-infrared light-blocking filter according to Experimental Example 23 (EX23) and Experimental Example 24 (EX24) exhibited an average transmittance of about 0% to about 30% in a region of about 950 nm to about 1100 nm of a near infrared light region (II). In particular, the near-infrared light-blocking filter according to Experimental Example 23 (EX23) has an absorption peak at a wavelength MW3 of about 1040 nm, that is, has a lowest transmittance or a highest absorption value at a wavelength of about 1040 nm. Alternatively, the near-infrared light-blocking filter according to Experimental Example 24 (EX24) has an absorption peak at a wavelength MW4 of about 1070 nm, that is, has a lowest transmittance or a highest absorption value at a wavelength of about 1070 nm.

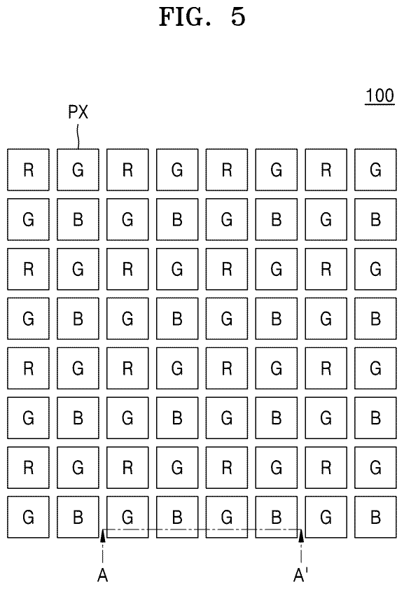

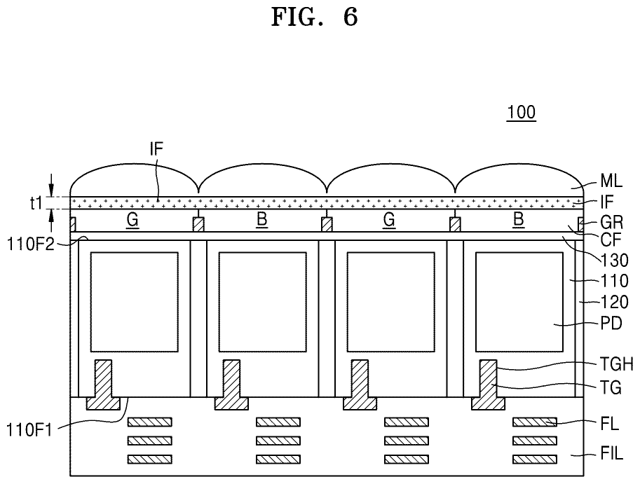

FIG. 5 is a plan view illustrating an image sensor 100 according to some embodiments, and FIG. 6 is a cross-sectional view taken along a line A-A′ in FIG. 5.

Referring to FIG. 5 and FIG. 6, an image sensor 100 may include a plurality of pixels PX arranged in a matrix shape. The image sensor 100 includes a plurality of photoelectric conversion regions PD formed in a semiconductor substrate 110. A pixel separation structure 120, which extends from a first surface 110F1 toward a second surface 110F2 of the semiconductor substrate 110 and defines the plurality of pixels PX, may be disposed. At least one photoelectric conversion region PD may be disposed in each pixel PX defined by the pixel separation structure 120.

A transfer gate TG may be disposed on the first surface 110F1 of the semiconductor substrate 110. The transfer gate TG may be disposed in a trench TGH to extend into the semiconductor substrate 110 and may be configured to control a photoelectron stored in the photoelectric conversion region PD. A pixel transistor may be further formed on the front surface of the semiconductor substrate 110 and may be configured to transfer to a flow diffusion region or reset the photoelectron, which is stored in the photoelectric conversion region PD. A front panel wiring layer FL and a front insulation layer FIL covering the transfer gate TG and a pixel transistor may be disposed on the first surface 110F1 of the semiconductor substrate 110.

An anti-reflection layer 130 may be disposed on the second surface 110F2 of the semiconductor substrate 110. A grid GR that divides pixel space corresponding to each of pixels PX may be disposed on an anti-reflection layer 130 and a color filter CF may be disposed within the pixel space defined by the grid GR on the anti-reflection layer 130. The color filter CF may sense green, blue, and red light according to the types of materials included in the color filter CF. For example, a plurality of pixels PX may include a green pixel G, a blue pixel B, and a red pixel R, wherein the green pixel G may include a color filter CF sensing green color, the blue pixel B may include a color filter CF sensing blue color, and the red pixel R may include a color filter CF sensing red color. In some embodiments, as illustrated in FIG. 5, the green pixel G, the blue pixel B, and the red pixel R may be arranged in the Bayer pattern. In some embodiments, an arrangement of the green pixel G, the blue pixel B, and the red pixel R may vary in various ways.

A near-infrared light-blocking filter IF may be disposed on the color filter CF. In some embodiments, the near-infrared light-blocking filter IF may be formed from the composition for a near-infrared light-blocking filter according to some embodiments, described above, and the composition for a near-infrared light-blocking filter may include a first cyanine dye, a second cyanine dye, and a third cyanine dye.

In some embodiments, the first cyanine dye may be a heptamethine cyanine dye expressed by General Formula 1 described above, may be configured to absorb light having a wavelength in a range of about 750 nm to about 850 nm, and may have a maximum absorption wavelength of about 760 nm to about 810 nm.

In some embodiments, the second cyanine dye may be a heptamethine cyanine dye expressed by General Formula 2 described above, may be configured to absorb light having a wavelength in a range of about 850 nm to about 950 nm, and may have a maximum absorption wavelength of about 870 nm to about 920 nm.

In some embodiments, the third cyanine dye may be a heptamethine cyanine dye represented by General Formula 3 described above, or a heptamethine cyanine dye represented by General Formula 4 described above, may be configured to absorb light having a wavelength in a range of about 950 nm to about 1100 nm, and may have a maximum absorption wavelength of about 1000 nm to about 1100 nm.

In some embodiments, the near-infrared light-blocking filter IF may be formed by spin coating the above-described composition for a near-infrared light-blocking filter according to some embodiments onto the color filter CF. For example, the near-infrared light-blocking filter IF may include the first cyanine dye, the second cyanine dye, and the third cyanine dye in a weight ratio of a:b:c, wherein a may be about 0.1 to about 0.9, or any range therein, b may be about 0.2 to about 1.0, or any range therein, and c may be about 0.6 to about 1.4, or any range therein. In some embodiments, a may be about 0.4 to about 0.6, b may be about 0.5 to about 0.7, and c may be about 0.9 to about 1.1.

In some embodiments, the near-infrared light-blocking filter IF may have a first average transmittance for light in a region of about 700 nm to about 1100 nm, and the first average transmittance may be 0% to 30%, or any range therein. In some embodiments, the first average transmittance may be about 0% to about 10%, or any range therein. In some embodiments, the near-infrared light-blocking filter IF may have a second average transmittance for light in a region of 400 nm to 700 nm, and the second average transmittance may be 60% to 100%, or any range therein. In some embodiments, the second average transmittance may be about 80% to about 100%, or any range therein.

In some embodiments, the near-infrared light-blocking filter IF may have a first thickness t1, and the first thickness t1 may be within about 500 nm to about 1000 nm, or any range therein.

In some embodiments, a microlens ML may be disposed on the near-infrared light-blocking filter IF. An anti-reflection layer composed of an inorganic material may not be provided between the near-infrared light-blocking filter IF and the microlens ML or between the near-infrared light-blocking filter IF and the color filter CF. In some embodiments, the near-infrared light-blocking filter IF may be in direct contact with the microlens ML disposed thereon. In other embodiments, a thin passivation layer may be provided between a near-infrared light-blocking filter IF and a microlens ML disposed thereon. In some embodiments, the near-infrared light-blocking filter IF may be in direct contact with the color filter CF disposed therebelow. In other embodiments, a thin passivation layer may be provided between a near-infrared light-blocking filter IF and a color filter layer CF disposed therebelow.

Generally, when near-infrared light or infrared light is transmitted into a silicon substrate, distortion of a red image may occur, and thus a method of absorbing the infrared light or near-infrared light by disposing a near-infrared light-blocking filter below a module lens has been suggested. Such a near-infrared light-blocking filter may include a filter layer including a dye applied on a top surface of a transparent substrate and an anti-reflection stack composed of an inorganic material applied on a bottom surface of the transparent substrate and has a relatively large thickness. The size of such a near-infrared light-blocking filter is relatively large, which causes a restriction on a miniaturization of an image sensor. In addition, a deviation in blocking characteristics depending on an angle of incidence is relatively large and noise is generated due to light leakage, which cause limitations.

According to some embodiments, the near-infrared light-blocking filter IF may have relatively high near-infrared light absorption (relatively uniform near-infrared light absorption) over an entire region of about 700 nm to about 1100 nm, or any range therein. In addition, a back surface of the image sensor 100 may be coated using a wafer-level skim, and no additional anti-reflection stack is needed to be provided. Therefore, the image sensor 100 may have excellent near-infrared light-blocking characteristics while having a compact size.

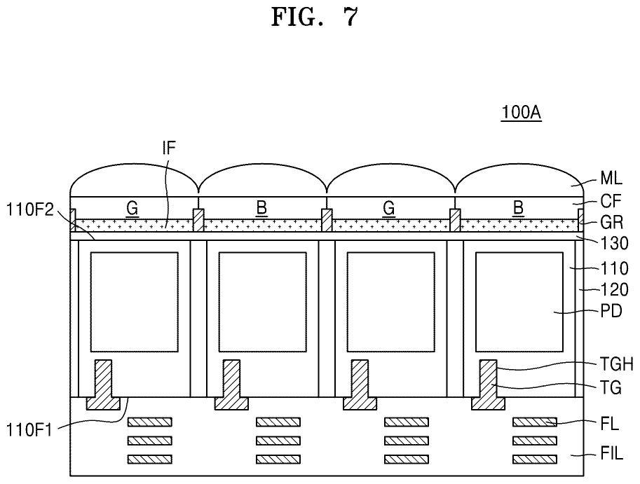

FIG. 7 is a plan view illustrating an image sensor 100A according to some embodiments.

Referring to FIG. 7, an anti-reflection layer 130 may be disposed on a second surface 110F2 of a semiconductor substrate 110, a grid GR that divides a pixel space corresponding to each pixel PX may be disposed on the anti-reflection layer 130, and a near-infrared light-blocking filter IF may be disposed in the pixel space defined by the grid GR on the anti-reflection layer 130. The color filter CF may be disposed on the near-infrared light-blocking filter IF.

In some embodiments, the near-infrared light-blocking filter IF may be formed from the above-described composition for a near-infrared light-blocking filter according to some embodiments, the composition for a near-infrared light-blocking filter is spin-coated and then dried in the pixel space defined by the grid GR after forming the grid GR on the anti-reflection layer 130 to thereby form the near-infrared light-blocking filter IF.

In some embodiments, the microlens ML may further include the composition for a near-infrared light-blocking filter according to some embodiments, for example, may further include the composition for a near-infrared light-blocking filter including a first cyanine dye, a second cyanine dye, and a third cyanine dye. For example, the microlens ML may include a light-transmissive organic material, and the composition for a near-infrared light-blocking filter may be further included in the light transmissive organic material. Therefore, the microlens ML may have near-infrared light-blocking characteristics.

In some embodiments, the microlens ML including the composition for a near-infrared light-blocking filter may be provided with the near-infrared light-blocking filter IF described with reference to FIG. 5 to FIG. 7. In some embodiments, the microlens ML including the composition for a near-infrared light-blocking filter may be provided in place of the near-infrared light-blocking filter IF described with reference to FIG. 5 to FIG. 7.

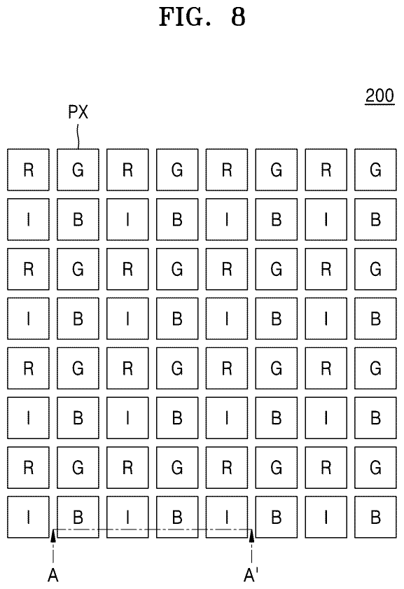

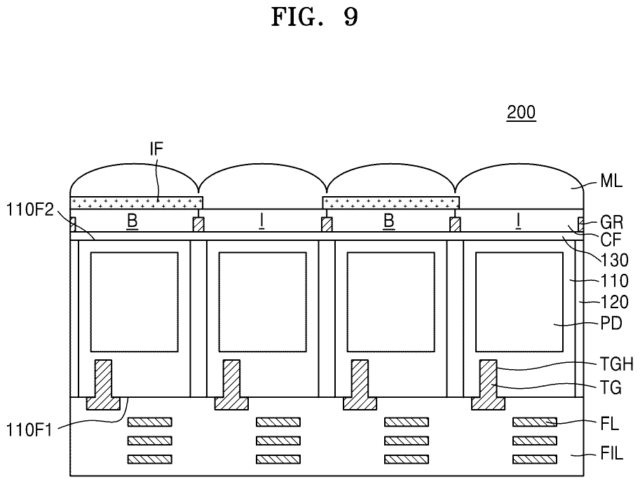

FIG. 8 is a plan view illustrating an image sensor 200 according to some embodiments, and FIG. 9 is a cross-sectional view taken along line A-A′ in FIG. 8.

Referring to FIG. 8 and FIG. 9, the image sensor 200 may include a plurality of pixels PX, and the plurality of pixels PX may include a green pixel G, a blue pixel B, a red pixel R, and an infrared light pixel I. In some embodiments, the infrared light pixel I may sense infrared light and may include a color filter CF sensing infrared light.

In some embodiments, the near-infrared light-blocking filter IF may be provided on the green pixel G, the blue pixel B, and the red pixel R, and may not be provided on the infrared light pixel I. For example, the near-infrared light-blocking filter IF may be disposed on a color filter CF corresponding to a green pixel G, on a color filter CF corresponding to a blue pixel B, and on a color filter CF corresponding to a red pixel R. The near-infrared light-blocking filter IF may not be disposed on the color filter CF corresponding to an infrared light pixel I.

In some embodiments, the near-infrared light-blocking filter IF may include the composition for a near-infrared light-blocking filter contained in a photosensitive material. For example, the near-infrared light-blocking filter IF may include a composition for a near-infrared light-blocking filter contained in a photoresist material, and for example, may include the composition for a near-infrared light-blocking filter contained in a photoresist material, the composition including the first cyanine dye, the second cyanine dye, and the third cyanine dye.

Since the near-infrared light-blocking filter IF includes the composition for a near-infrared light-blocking filter contained in the photoresist material, the near-infrared light-blocking filter IF may be patterned by a lithography process, for example, by a photoresist application process, an exposure process, and a developing process.

In some embodiments, the near-infrared light-blocking filter IF may be formed using a composition for a near-infrared light-blocking filter contained in the photosensitive material, and the near-infrared light-blocking filter IF may be formed on a color filter CF corresponding to a green pixel G, blue pixel B, or a red pixel R by a lithography process and may not be formed on a color filter CF corresponding to an infrared light pixel I. In some embodiments, as described in FIG. 9, the near-infrared light-blocking filter IF may be on a color filter CF, and the microlens ML may be disposed on the near-infrared light-blocking filter IF.

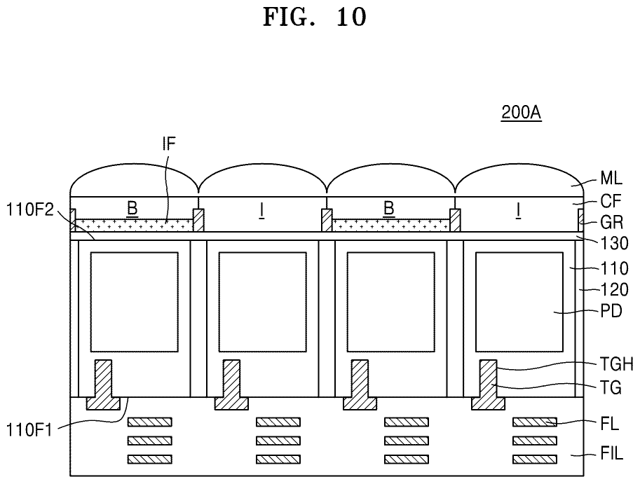

FIG. 10 is a plan view illustrating an image sensor 200A according to some embodiments.

Referring to FIG. 10, a plurality of pixels PX may include a green pixel G, a blue pixel B, a red pixel R, and an infrared light pixel I. The near-infrared light-blocking filter IF may be provided on the green pixel G, the blue pixel B, and the red pixel R, and may not be provided on the infrared light pixel I. For example, the near-infrared light-blocking filter IF may be disposed below a color filter CF corresponding to a green pixel G, below a color filter CF corresponding blue pixel B, and below a color filter CF corresponding red pixel R. The near-infrared light-blocking filter IF may not be disposed below the color filter CF corresponding to an infrared light pixel I. In some embodiments, the near-infrared light-blocking filter IF may be disposed on the second surface 110F2, (for example, on the anti-reflection layer 130), of the semiconductor substrate 110 in the pixel space defined by the grid GR, and the color filter CF may be disposed on the near-infrared light-blocking filter IF.

In some embodiments, according to the inventive concept, the near-infrared light-blocking filter includes a mixture of a first cyanine dye, a second cyanine dye, and a third cyanine dye, and the mixture of the first cyanine dye, the second cyanine dye, and the third cyanine dye may have a transmittance of about 0% to about 30% or any range therein for infrared light in a region of about 700 nm to about 1100 nm, or any range therein. The near-infrared light-blocking filter may be coated on a back surface of the image sensor using a wafer-level skim, and thus the image sensor may have excellent near-infrared light-blocking characteristics while having a compact size.

As described above, embodiments have been described in the specification with reference to the drawings. Although the embodiments have been described using specific terms in this specification, they are only used for the purpose of explaining the technical idea of the inventive concept and are not used to limit the scope of the inventive concept described in the claims. Therefore, it should be understood that various changes, modifications, and other equivalent embodiments can be made by one ordinary skilled in the art. Therefore, the true technical protection scope of the inventive concept should be determined by the technical spirit of the following claims.

While the inventive concept has been particularly shown and described with reference to some embodiments thereof, it will be understood that various changes in form and details may be made therein without departing from the spirit and scope of the following claims.

What is claimed is:

1. A composition for a near-infrared light-blocking filter which is employed in an image sensor, the composition comprising a mixture of:
a first cyanine dye; a second cyanine dye; and a third cyanine dye,
wherein the first cyanine dye is represented by General Formula 1,
the second cyanine dye is represented by General Formula 2, and
the third cyanine dye is represented by General Formula 3 or General Formula 4: 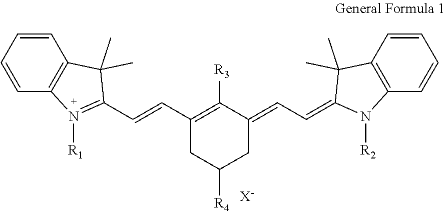
wherein, in General Formula 1, R₁ and R₂ are each independently a linear or branched alkyl group having a carbon number 6 to 12, R₃ is at least one of a halogen element, a phenol group, a p-hydroxybenzoic acid group, a methylparaben group, a methyl p-aminobenzoate group, a p-aminobenzoic acid group, an aniline group, a benzenesulfinic acid group, and a diphenylamine group, R₄ is a n-butyl group, a sec-butyl group, an iso-butyl group, a tert-butyl group, a phenyl group, a benzyl group, a tert-butylphenyl group, a cyclopropyl group, a cyclobutyl group, a cyclopentyl group, a cyclohexyl group, a cyclohexenyl group, a cycloheptyl group, a cyclooctyl group, a methoxyl group, an ethoxyl group, or a propoxyl group, and X is a non-metallic element; 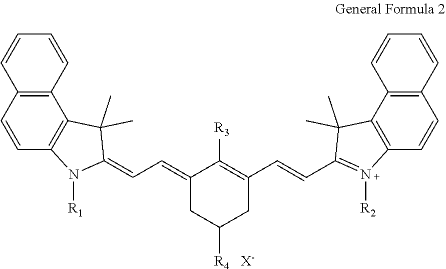
wherein, in General Formula 2, R₁ and R₂ are each independently a linear or branched alkyl group having a carbon number of 6 to 12, R₃ is at least one of a halogen element, a phenol group, a p-hydroxybenzoic acid group, a methylparaben group, a methyl p-aminobenzoate group, a p-aminobenzoic acid group, an aniline group, a benzenesulfinic acid group, and a diphenylamine group, R₄ is a n-butyl group, a sec-butyl group, an iso-butyl group, a tert-butyl group, a phenyl group, a benzyl group, a tert-butylphenyl group, a cyclopropyl group, a cyclobutyl group, a cyclopentyl group, a cyclohexyl group, a cyclohexenyl group, a cycloheptyl group, a cyclooctyl group, a methoxyl group, an ethoxyl group, or a propoxyl group, and X is a non-metallic element; 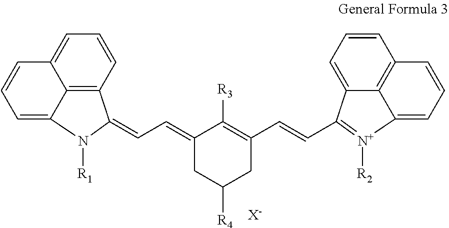
wherein, in General Formula 3, R₁ and R₂ are each independently a linear or branched alkyl group having a carbon number of 6 to 12, R₃ is at least one of a halogen element, a phenol group, a p-hydroxybenzoic acid group, a methylparaben group, a methyl p-aminobenzoate group, a p-aminobenzoic acid group, an aniline group, a benzenesulfinic acid group, and a diphenylamine group, R₄ is a n-butyl group, a sec-butyl group, an iso-butyl group, a tert-butyl group, a phenyl group, a benzyl group, a tert-butylphenyl group, a cyclopropyl group, a cyclobutyl group, a cyclopentyl group, a cyclohexyl group, a cyclohexenyl group, a cycloheptyl group, a cyclooctyl group, a methoxyl group, an ethoxyl group, or a propoxyl group, and X is a non-metallic element; 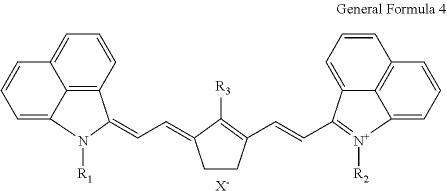
wherein, in General Formula 4, R₁ and R₂ are each independently a linear or branched alkyl group having a carbon number of 6 to 12, R₃ is at least one of a halogen element, a phenol group, a p-hydroxybenzoic acid group, a methylparaben group, a methyl p-aminobenzoate group, a p-aminobenzoic acid group, an aniline group, a benzenesulfinic acid group, and a diphenylamine group, and X is a non-metal element.

2. The composition of claim 1, wherein the composition for a near-infrared light-blocking filter comprises the first cyanine dye, the second cyanine dye, and the third cyanine dye in a weight ratio of a:b:c,
wherein a is about 0.1 to about 0.9,
b is about 0.2 to about 1.0, and
c is about 0.6 to about 1.4.

3. The composition of claim 1, wherein the composition for a near-infrared light-blocking filter comprises the first cyanine dye, the second cyanine dye, and the third cyanine dye in a weight ratio of a:b:c,
wherein a is about 0.4 to about 0.6,
b is about 0.5 to about 0.7, and
c is about 0.9 to about 1.1.

4. The composition of claim 1,
wherein the first cyanine dye is configured to absorb light having a wavelength in a range of about 750 nm to about 850 nm,
the second cyanine dye is configured to absorb light having a wavelength in a range of about 850 nm to about 950 nm, and
the third cyanine dye is configured to absorb light having a wavelength in a range of about 950 nm to about 1100 nm.

5. The composition of claim 4,
wherein the first cyanine dye has a maximum absorption wavelength of about 760 nm to about 810 nm,
the second cyanine dye has a maximum absorption wavelength of about 870 nm to about 920 nm, and
the third cyanine dye has a maximum absorption wavelength of about 1000 nm to about 1100 nm.

6. An image sensor comprising: a substrate including a first surface and a second surface opposite to the first surface, the substrate comprising a plurality of pixels, and each of the plurality of pixels comprising a photoelectric conversion region; and
a near-infrared light-blocking filter disposed on the second surface of the substrate,
wherein the near-infrared light-blocking filter comprises a mixture of a first cyanine dye, a second cyanine dye, and a third cyanine dye,
the first cyanine dye is represented by General Formula 1,
the second cyanine dye is represented by General Formula 2, and
the third cyanine dye is represented by General Formula 3 or General Formula 4: 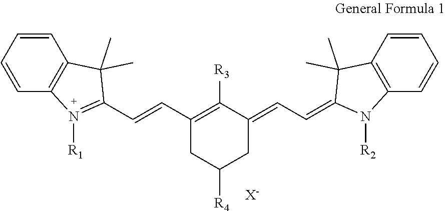
wherein, in General Formula 1, R₁ and R₂ are each independently a linear or branched alkyl group having a carbon number of 6 to 12, R₃ is at least one of a halogen element, a phenol group, a p-hydroxybenzoic acid group, a methylparaben group, a methyl p-aminobenzoate group, a p-aminobenzoic acid group, an aniline group, a benzenesulfinic acid group, and a diphenylamine group, R₄ is a n-butyl group, a sec-butyl group, an iso-butyl group, a tert-butyl group, a phenyl group, a benzyl group, a tert-butylphenyl group, a cyclopropyl group, a cyclobutyl group, a cyclopentyl group, a cyclohexyl group, a cyclohexenyl group, a cycloheptyl group, a cyclooctyl group, a methoxyl group, an ethoxyl group, or a propoxyl group, and X is a non-metallic element; 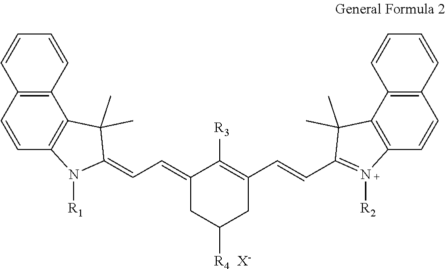
wherein, in General Formula 2, R₁ and R₂ are each independently a linear or branched alkyl group having a carbon number of 6 to 12, R₃ is at least one of a halogen element, a phenol group, a p-hydroxybenzoic acid group, a methylparaben group, a methyl p-aminobenzoate group, a p-aminobenzoic acid group, an aniline group, a benzenesulfinic acid group, and a diphenylamine group, R₄ is a n-butyl group, a sec-butyl group, an iso-butyl group, a tert-butyl group, a phenyl group, a benzyl group, a tert-butylphenyl group, a cyclopropyl group, a cyclobutyl group, a cyclopentyl group, a cyclohexyl group, a cyclohexenyl group, a cycloheptyl group, a cyclooctyl group, a methoxyl group, an ethoxyl group, or a propoxyl group, and X is a non-metallic element; 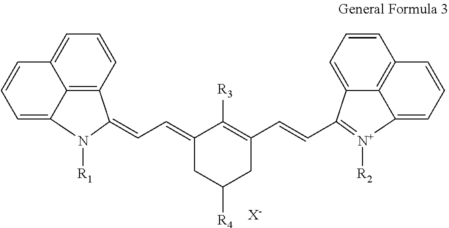
wherein, in General Formula 3, R₁ and R₂ are each independently a linear or branched alkyl group having a carbon number of 6 to 12, R₃ is at least one of a halogen element, a phenol group, a p-hydroxybenzoic acid group, a methylparaben group, a methyl p-aminobenzoate group, a p-aminobenzoic acid group, an aniline group, a benzenesulfinic acid group, and a diphenylamine group, R₄ is a n-butyl group, a sec-butyl group, an iso-butyl group, a tert-butyl group, a phenyl group, a benzyl group, a tert-butylphenyl group, a cyclopropyl group, a cyclobutyl group, a cyclopentyl group, a cyclohexyl group, a cyclohexenyl group, a cycloheptyl group, a cyclooctyl group, a methoxyl group, an ethoxyl group, or a propoxyl group, and X is a non-metallic element; 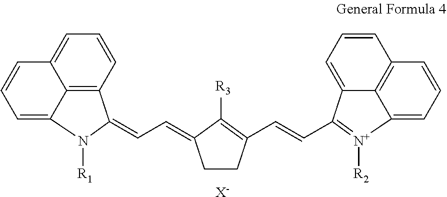
wherein, in General Formula 4, R₁ and R₂ are each independently a linear or branched alkyl group having a carbon number of 6 to 12, R₃ is at least one of a halogen element, a phenol group, a p-hydroxybenzoic acid group, a methylparaben group, a methyl p-aminobenzoate group, a p-aminobenzoic acid group, an aniline group, a benzenesulfinic acid group, and a diphenylamine group, and X is a non-metal element.

7. The image sensor of claim 6,
wherein, in General Formula 1, X is at least one of a halogen element, phosphoric acid, hexafluorophosphate, perchlorate, tetrafluoroborate, p-toluenesulfonate, bis(trifluoromethanesulfonyl)azanide (TFSI), and tetrakis[3,5-bis(trifluoromethyl)phenyl]borate (BARF),
in General Formula 2, X is at least one of a halogen element, phosphoric acid, hexafluorophosphate, perchlorate, tetrafluoroborate, TFSI, and tBARF,
in General Formula 3, X is at least one of a halogen element, phosphoric acid, hexafluorophosphate, perchlorate, tetrafluoroborate, p-toluenesulfonate, TFSI, and tBARF, and
in General Formula 4, X is at least one of a halogen element, phosphoric acid, hexafluorophosphate, perchlorate, tetrafluoroborate, p-toluenesulfonate, TFSI, and tBARF.

8. The image sensor of claim 6,
wherein the near-infrared light-blocking filter comprises the first cyanine dye, the second cyanine dye, and the third cyanine dye in a weight ratio of a:b:c,
a is about 0.1 to about 0.9,
b is about 0.2 to about 1.0, and
c is about 0.6 to about 1.4.

9. The image sensor of claim 6,
wherein the near-infrared light-blocking filter comprises the first cyanine dye, the second cyanine dye, and the third cyanine dye in a weight ratio of a:b:c,
a is about 0.4 to about 0.6,
b is about 0.5 to about 0.7, and
c is about 0.9 to about 1.1.

10. The image sensor of claim 6,
wherein the first cyanine dye is configured to absorb light having a wavelength in a range of about 750 nm to about 850 nm,
the second cyanine dye is configured to absorb light having a wavelength in a range of about 850 nm to about 950 nm, and
the third cyanine dye is configured to absorb light having a wavelength in a range of about 850 nm to about 1100 nm.

11. The image sensor of claim 10,
wherein the first cyanine dye has a maximum absorption wavelength of about 760 nm to about 810 nm,
the second cyanine dye has a maximum absorption wavelength of about 870 nm to about 920 nm, and
the third cyanine dye has a maximum absorption wavelength of about 1000 nm to about 1100 nm.

12. The image sensor of claim 6,
wherein the near-infrared light-blocking filter has a first average transmittance for light in a range of about 700 nm to about 1100 nm, and
the first average transmittance is about 0% to about 30%.

13. The image sensor of claim 6,
wherein the near-infrared light-blocking filter has a second average transmittance for light in a range of about 400 nm to about 700 nm, and
the second average transmittance is about 60% to about 100%.

14. The image sensor of claim 6, further comprising:
a color filter disposed on the second surface of the substrate and the near-infrared light-blocking filter; and
a microlens disposed on the near-infrared light-blocking filter.

15. The image sensor of claim 6, further comprising:
a color filter disposed on the near-infrared light-blocking filter; and
a microlens disposed on the color filter.

16. The image sensor of claim 6,
wherein the plurality of pixels comprises a red pixel, a green pixel, and a blue pixel, and
the near-infrared light-blocking filter is provided on the red pixel, the green pixel, and the blue pixel.

17. The image sensor of claim 6,
wherein the plurality of pixels comprises a red pixel, a green pixel, a blue pixel, and an infrared light pixel,
the near-infrared light-blocking filter is provided on the red pixel, the green pixel, and the blue pixel, and
the near-infrared light-blocking filter is not provided on the infrared light pixel.

18. An image sensor comprising: a substrate including a first surface and a second surface opposite to the first surface, the substrate comprising a plurality of pixels, and each of the plurality of pixels comprising a photoelectric conversion region; and
an anti-reflection layer disposed on the second surface of the substrate; and
a color filter disposed on the anti-reflection layer;
a near-infrared light-blocking filter disposed on the color filter layer; and
a microlens disposed on the near-infrared light-blocking filter,
wherein the near-infrared light-blocking filter comprises a mixture of a first cyanine dye, a second cyanine dye, and a third cyanine dye, and a weight ratio of the first cyanine dye, the second cyanine dye, and the third cyanine dye is a:b:c, and a is about 0.4 to about 0.6, b is about 0.5 to about 0.7, c is about 0.9 to about 1.1,
the first cyanine dye comprises heptamethine cyanine dye, is configured to absorb light having a wavelength in a range of about 750 nm to about 850 nm, and has a maximum absorption wavelength of about 760 nm to about 810 nm,
the second cyanine dye comprises heptamethine cyanine dye, is configured to absorb light having a wavelength in a range of about 850 nm to about 950 nm, and has a maximum absorption wavelength of about 870 nm to about 920 nm, and
the third cyanine dye comprises heptamethine cyanine dye, is configured to absorb light having a wavelength in a range of about 950 nm to about 1100 nm, and has a maximum absorption wavelength of about 1000 nm to about 1100 nm.

19. The image sensor of claim 18,
wherein the first cyanine dye is represented by General Formula 1, and
the second cyanine dye is represented by General Formula 2: 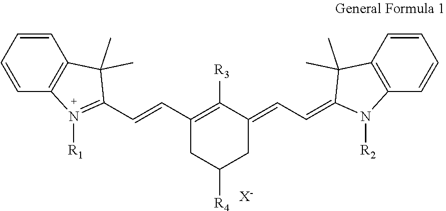
wherein, in General Formula 1, R₁ and R₂ are each independently a linear or branched alkyl group having a carbon number of 6 to 12, R₃ is at least one of a halogen element, a phenol group, a p-hydroxybenzoic acid group, a methylparaben group, a methyl p-aminobenzoate group, a p-aminobenzoic acid group, an aniline group, a benzenesulfinic acid group, and a diphenylamine group, R₄ is a n-butyl group, a sec-butyl group, an iso-butyl group, a tert-butyl group, a phenyl group, a benzyl group, a tert-butylphenyl group, a cyclopropyl group, a cyclobutyl group, a cyclopentyl group, a cyclohexyl group, a cyclohexenyl group, a cycloheptyl group, a cyclooctyl group, a methoxyl group, an ethoxyl group, or a propoxyl group, and X is a non-metallic element; 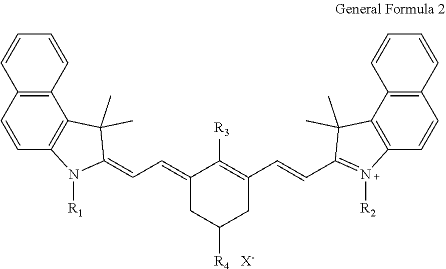
wherein, in General Formula 2, R₁ and R₂ are each independently a linear or branched alkyl group having a carbon number of 6 to 12, R₃ is at least one of a halogen element, a phenol group, a p-hydroxybenzoic acid group, a methylparaben group, a methyl p-aminobenzoate group, a p-aminobenzoic acid group, an aniline group, a benzenesulfinic acid group, and a diphenylamine group, R₄ is a n-butyl group, a sec-butyl group, an iso-butyl group, a tert-butyl group, a phenyl group, a benzyl group, a tert-butylphenyl group, a cyclopropyl group, a cyclobutyl group, a cyclopentyl group, a cyclohexyl group, a cyclohexenyl group, a cycloheptyl group, a cyclooctyl group, a methoxyl group, an ethoxyl group, or a propoxyl group, and X is a non-metallic element.

20. The image sensor of claim 19,
wherein the third cyanine dye is represented by General Formula 3 or General Formula 4: 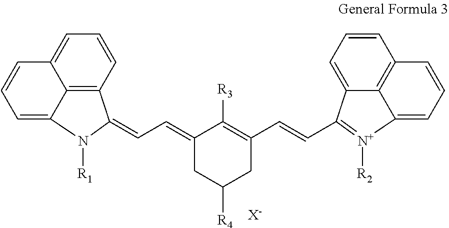
wherein, in General Formula 3, R₁ and R₂ are each independently a linear or branched alkyl group having a carbon number of 6 to 12, R₃ is at least one of a halogen element, a phenol group, a p-hydroxybenzoic acid group, a methylparaben group, a methyl p-aminobenzoate group, a p-aminobenzoic acid group, an aniline group, a benzenesulfinic acid group, and a diphenylamine group, R₄ is a n-butyl group, a sec-butyl group, an iso-butyl group, a tert-butyl group, a phenyl group, a benzyl group, a tert-butylphenyl group, a cyclopropyl group, a cyclobutyl group, a cyclopentyl group, a cyclohexyl group, a cyclohexenyl group, a cycloheptyl group, a cyclooctyl group, a methoxyl group, an ethoxyl group, or a propoxyl group, and X is a non-metallic element; 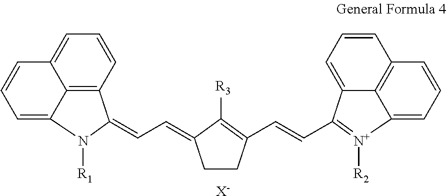
wherein, in General Formula 4, R₁ and R₂ are each independently a linear or branched alkyl group having a carbon number of 6 to 12, R₃ is at least one of a halogen element, a phenol group, a p-hydroxybenzoic acid group, a methylparaben group, a methyl p-aminobenzoate group, a p-aminobenzoic acid group, an aniline group, a benzenesulfinic acid group, and a diphenylamine group, and X is a non-metal element.
